(19) United States
(12) Patent Application Publication
(10) Pub. No.: US 2025/0126977 A1
(43) Pub. Date: Apr. 17, 2025

(54) DISPLAY APPARATUS

(71) Applicant: SEMICONDUCTOR ENERGY LABORATORY CO., LTD., Atsugi-shi, Kanagawa-ken (JP)

(72) Inventors: Koji KUSUNOKI, Isehara, Kanagawa (JP); Daisuke KUBOTA, Atsugi, Kanagawa (JP); Kensuke YOSHIZUMI, Atsugi, Kanagawa (JP); Junpei SUGAO, Isehara, Kanagawa (JP)

(21) Appl. No.: 18/682,322

(22) PCT Filed: Aug. 1, 2022
(86) PCT No.: PCT/IB2022/057106

§ 371 Date: Feb. 8, 2024

(30) Foreign Application Priority Data
Aug. 12, 2021 (JP) 2021-131595

(51) Int. Cl. H10K 59/122

(52) U.S. Cl. CPC H10K 59/122

(57) ABSTRACT

A display apparatus with a high aperture ratio is provided. The display apparatus includes a first pixel, a second pixel placed adjacent to the first pixel, a first conductive layer, a second conductive layer, and a first insulating layer. The first pixel includes a first pixel electrode, a first EL layer over the first pixel electrode, and a common electrode over the first EL layer. The second pixel includes a second pixel electrode, a second EL layer over the second pixel electrode, and the common electrode over the second EL layer. The first conductive layer is placed over the common electrode. The first insulating layer is placed over the first conductive layer. The second conductive layer is placed over the first insulating layer. One or both of the first conductive layer and the second conductive layer overlap with a region interposed between the first EL layer and the second EL layer. A side surface of the first EL layer and a side surface of the second EL layer are placed to face each other.

### TECHNICAL FIELD

One embodiment of the present invention relates to a display apparatus. One embodiment of the present invention relates to an electronic device.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a laptop computer. Furthermore, higher resolution has been required for a stationary display apparatus such as a television device or a monitor device along with an increase in definition. An example of a device required to have the highest resolution is a device for virtual reality (VR) or augmented reality (AR).

Examples of a display apparatus that can be used for a display panel include, typically, a liquid crystal display apparatus, a light-emitting apparatus including a light-emitting element such as an organic EL (Electro Luminescence) element or a light-emitting diode (LED), and electronic paper performing display by an electrophoretic method or the like.

For example, the basic structure of an organic EL element is a structure where a layer containing a light-emitting organic compound is interposed between a pair of electrodes. By applying voltage to this element, light emission can be obtained from the light-emitting organic compound. A display apparatus using such an organic EL element does not need a backlight that is necessary for a liquid crystal display apparatus and the like; thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

An object of one embodiment of the present invention is to provide a display apparatus with a high aperture ratio. An object of one embodiment of the present invention is to provide a display apparatus with high display quality. An object of one embodiment of the present invention is to provide a highly reliable display apparatus. An object of one embodiment of the present invention is to provide a display apparatus that can easily achieve a higher resolution. An object of one embodiment of the present invention is to provide a display apparatus with low power consumption.

An object of one embodiment of the present invention is to at least alleviate at least one of problems of the conventional technique.

Note that the description of these objects does not preclude the existence of other objects. Note that one embodiment of the present invention does not have to achieve all the objects. Note that objects other than these can be derived from the description of the specification, the drawings, the claims, and the like.

### Means for Solving the Problems

One embodiment of the present invention is a display apparatus including a first pixel, a second pixel placed adjacent to the first pixel, a first conductive layer, a second conductive layer, and a first insulating layer. The first pixel includes a first pixel electrode, a first EL layer over the first pixel electrode, and a common electrode over the first EL layer. The second pixel includes a second pixel electrode, a second EL layer over the second pixel electrode, and the common electrode over the second EL electrode. The first conductive layer is placed over the common electrode. The first insulating layer is placed over the first conductive layer. The second conductive layer is placed over the first insulating layer. One or both of the first conductive layer and the second conductive layer overlap with a region interposed between the first EL layer and the second EL layer. A side surface of the first EL layer and a side surface of the second EL layer are placed to face each other.

In the above, the display apparatus preferably includes a second insulating layer and a third insulating layer over the second insulating layer. The second insulating layer preferably contains an inorganic material. The third insulating layer preferably contains an organic material. Part of the second insulating layer and part of the third insulating layer are preferably provided to be interposed between an end portion of the side surface the first EL layer and an end portion of the side surface of the second EL layer. Another part of the third insulating layer preferably overlaps with part of the top surface of the first EL layer and part of the top surface of the second EL layer with the second insulating layer therebetween.

In the above, one or both of the first conductive layer and the second conductive layer preferably include a region overlapping with the third insulating layer.

In the above, each of the side surface of the first conductive layer and the side surface of the second conductive layer is preferably located inward from an end portion of the third insulating layer in a cross-sectional view.

In the above, the common electrode is preferably placed over the third insulating layer.

In the above, the display apparatus preferably includes a first substrate and a second substrate. The first pixel and the second pixel are preferably placed over the first substrate. The second substrate is preferably bonded to a surface where the first insulating layer and the second conductive layer of the first substrate are placed with an adhesive layer.

In the above, the first pixel preferably includes a common layer placed between the first EL layer and the common electrode and the second pixel preferably includes the common layer provided between the second EL layer and the common electrode.

In the above, the display apparatus preferably includes a region in which the distance between the first pixel electrode and the second pixel electrode is less than or equal to 8 μm.

### Effect of the Invention

According to one embodiment of the present invention, a display apparatus with a high aperture ratio can be provided. A display apparatus with high display quality can be provided. A highly reliable display apparatus can be provided. A display apparatus that can easily achieve a higher resolution can be provided. A display apparatus with low power consumption can be provided. At least one of problems of the conventional technique can be at least alleviated.

Note that the description of these effects does not preclude the existence of other effects. Note that one embodiment of the present invention does not need to have all the effects. Note that effects other than these can be derived from the description of the specification, the drawings, the claims, and the like.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A and FIG. 2B are enlarged cross-sectional views each illustrating an example of a display apparatus.

FIG. 3A to FIG. 3C are cross-sectional views each illustrating an example of a display apparatus.

FIG. 4A and FIG. 4B are cross-sectional views each illustrating an example of a display apparatus.

FIG. 5A to FIG. 5C are cross-sectional views each illustrating an example of a display apparatus.

FIG. 6A and FIG. 6B are cross-sectional views each illustrating an example of a display apparatus.

FIG. 7A to FIG. 7C are cross-sectional views each illustrating an example of a display apparatus.

FIG. 8A to FIG. 8C are cross-sectional views each illustrating an example of a display apparatus.

FIG. 9A to FIG. 9F are cross-sectional views each illustrating an example of a display apparatus.

FIG. 10A to FIG. 10F are top views each illustrating an example of a pixel.

FIG. 11A to FIG. 11H are top views each illustrating an example of a pixel.

FIG. 12A to FIG. 12J are top views each illustrating an example of a pixel.

FIG. 13A to FIG. 13C are diagrams each illustrating a structure example of a touch sensor.

FIG. 14 is a diagram illustrating a structure example of a touch sensor and a pixel.

FIG. 15A and FIG. 15B are diagrams each illustrating a structure example of a touch sensor and a pixel.

FIG. 16 is a diagram illustrating a structure example of a touch sensor and a pixel.

FIG. 17 is a diagram illustrating a structure example of a touch sensor and a pixel.

FIG. 18 is a perspective view illustrating an example of a display apparatus.

FIG. 19A to FIG. 19C are cross-sectional views each illustrating an example of a display apparatus.

FIG. 20A and FIG. 20B are cross-sectional views each illustrating an example of a display apparatus.

FIG. 21A and FIG. 21B are cross-sectional views each illustrating an example of a transistor. FIG. 21C to FIG. 21E are cross-sectional views each illustrating an example of a display apparatus.

FIG. 22A is a block diagram illustrating an example of a display apparatus. FIG. 22B to FIG. 22D are diagrams each illustrating an example of a pixel circuit.

FIG. 23A to FIG. 23D are diagrams each illustrating an example of a transistor.

FIG. 24A to FIG. 24F are diagrams each illustrating a structure example of a light-emitting device.

FIG. 25A to FIG. 25F are diagrams each illustrating an example of an electronic device.

FIG. 26A to FIG. 26G are diagrams each illustrating an example of an electronic device.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of embodiments below.

Note that in structures of the invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Thus, they are not limited to the illustrated scale.

Note that in this specification and the like, ordinal numbers such as “first” and “second” are used in order to avoid confusion among components and do not limit the number.

In this specification and the like, a display apparatus may be rephrased as an electronic device.

In this specification and the like, a device manufactured using a metal mask or an FMM (fine metal mask) is sometimes referred to as a device having an MM (metal mask) structure. In addition, in this specification and the like, a device manufactured without using a metal mask or an FMM is sometimes referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be distinguished from each other depending on the cross-sectional shape, properties, or the like. Furthermore, one layer may have two or three functions of the carrier-injection layer, the carrier-transport layer, and the carrier-blocking layer in some cases.

### Embodiment 1

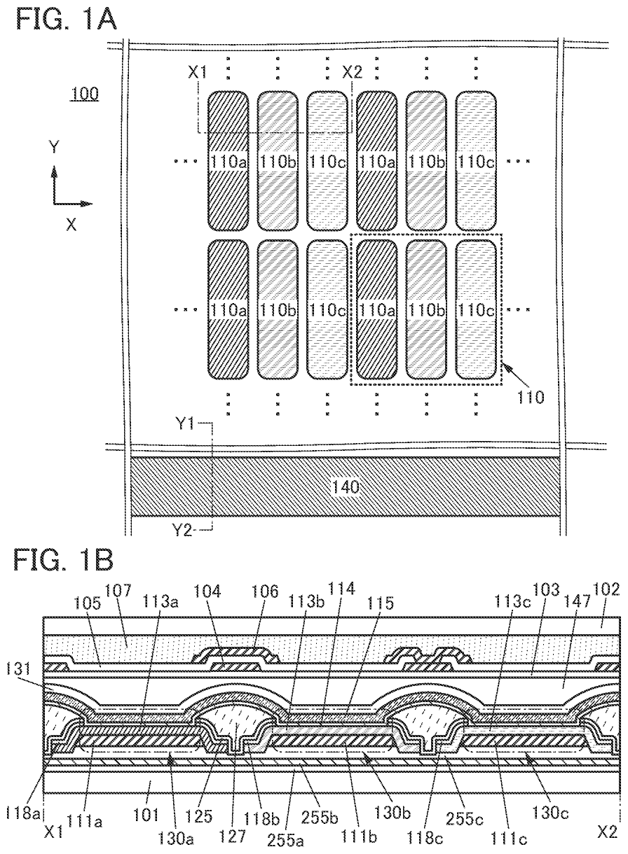

In this embodiment, a display apparatus of one embodiment of the present invention is described with reference to FIG. 1 to FIG. 9.

One embodiment of the present invention is a display apparatus including a display portion capable of full-color display. The display portion includes a first subpixel and a second subpixel that emit light of different colors. The first-subpixel includes a first light-emitting device that emits blue light and the second subpixel includes a second light-emitting device that emits light of a color different from the color of light emitted by the first light-emitting device. At least one kind of material is different between the first light-emitting device and the second light-emitting device; for example, the light-emitting devices contain different light-emitting materials. That is, light-emitting devices for different emission colors are separately formed in the display apparatus of one embodiment of the present invention.

A structure in which light-emitting layers in light-emitting devices of different colors (for example, blue (B), green (G), and red (R)) are separately formed or separately patterned is sometimes referred to as an SBS (Side By Side) structure. The SBS structure allows optimization of materials and structures of light-emitting devices and thus can extend freedom of choice of the materials and the structures, which makes it easy to improve the luminance and the reliability.

In the case of manufacturing a display apparatus including a plurality of light-emitting devices emitting light of different colors, light-emitting layers emitting light of different colors each need to be formed into an island shape. Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be deposited by a vacuum evaporation method using a metal mask (also referred to as a shadow mask). However, this method causes a deviation from the designed shape and position of the island-shaped light-emitting layer due to various influences such as the accuracy of the metal mask, the positional deviation between the metal mask and a substrate, a warp of the metal mask, and the vapor-scattering-induced expansion of outline of the deposited film; accordingly, it is difficult to achieve high resolution and a high aperture ratio of the display apparatus. In addition, the outline of the layer may blur during vapor deposition, whereby the thickness of an end portion may be reduced. That is, the thickness of the island-shaped light-emitting layer may vary from area to area. In the case of manufacturing a display apparatus with a large size, high definition, or high resolution, the manufacturing yield might be reduced because of low dimensional accuracy of the metal mask and deformation due to heat or the like.

In a method for manufacturing a display apparatus of one embodiment of the present invention, a first layer (also referred to as an EL layer or part of an EL layer) including a light-emitting layer emitting light of a first color is formed over the entire surface, and then a first mask layer is formed over the first layer. Then, a first resist mask is formed over the first mask layer and the first layer and the first mask layer are processed using the first resist mask, so that an island-shaped first layer is formed. Next, in a manner similar to that for the first layer, a second layer (also referred to as an EL layer or part of an EL layer) including a light-emitting layer emitting light of a second color is formed into an island shape using a second mask layer and a second resist mask.

In this specification and the like, a mask film and a mask layer are each positioned above at least a light-emitting layer (specifically, a layer processed into an island shape among layers included in an EL layer) and has a function of protecting the light-emitting layer in the manufacturing step. Note that in this specification and the like, the mask film may be referred to as a sacrificial film, and the mask layer may be referred to as a sacrificial layer.

In the case of processing the light-emitting layer into an island shape, a conceivable structure is such that the light-emitting layer is processed by performing a photolithography method directly on the light-emitting layer. In that case, damage to the light-emitting layer (e.g., processing damage) might significantly degrade the reliability. In view of the above, in the manufacture of the display apparatus of one embodiment of the present invention, a mask layer or the like is preferably formed over a functional layer above the light-emitting layer (e.g., a carrier-blocking layer, a carrier-transport layer, or a carrier-injection layer, more specifically, a hole-blocking layer, an electron-transport layer, or an electron-injection layer), followed by the processing of the light-emitting layer into an island shape. Such a method provides a highly reliable display apparatus.

As described above, the island shaped EL layers manufactured in the method for manufacturing a display apparatus of one embodiment of the present invention are formed not by using a metal mask having a fine pattern but by processing an EL layer deposited over the entire surface. Accordingly, a high-resolution display apparatus or a display apparatus with a high aperture ratio, each of which has been difficult to achieve, can be obtained. Moreover, EL layers can be formed separately for the respective colors, enabling the display apparatus to perform extremely clear display with high contrast and high display quality. In addition, a mask layer provided over an EL layer can reduce damage to the EL layer in the manufacturing process of the display apparatus, increasing the reliability of the light-emitting device.

It is difficult to reduce the distance between adjacent light-emitting devices to less than m with a formation method using a fine metal mask, for example. However, the method using a photolithography method according to one embodiment of the present invention can shorten the distance between adjacent light-emitting devices, adjacent EL layers, or adjacent pixel electrodes to less than 10 μm, less than or equal to 8 μm, less than or equal to 5 μm, less than or equal to 3 μm, less than or equal to 2 μm, less than or equal to 1.5 μm, less than or equal to 1 μm, or even less than or equal to 0.5 μm, for example, in a process over a glass substrate. Using a light exposure apparatus for LSI can further shorten the distance between adjacent light-emitting devices, adjacent EL layers, or adjacent pixel electrodes to less than or equal to 500 nm, less than or equal to 200 nm, less than or equal to 100 nm, or even less than or equal to 50 nm, for example, in a process over a Si wafer. Accordingly, the area of a non-light-emitting region that could exist between two light-emitting devices can be significantly reduced, and the aperture ratio can be close to 100%. For example, the display apparatus of one embodiment of the present invention can achieve an aperture ratio higher than or equal to 40%, higher than or equal to 50%, higher than or equal to 60%, higher than or equal to 70%, higher than or equal to 80%, or higher than or equal to 90%; that is, an aperture ratio lower than 100%.

Increasing the aperture ratio of the display apparatus can improve the reliability of the display apparatus. Specifically, with reference to the lifetime of a display apparatus including an organic EL device and having an aperture ratio of 10%, a display apparatus having an aperture ratio of 20% (that is, two times the aperture ratio of the reference) has a lifetime approximately 3.25 times as long as that of the reference, and a display apparatus having an aperture ratio of 40% (i.e., four times the aperture ratio of the reference) has a lifetime approximately 10.6 times as long as that of the reference. Thus, the density of current flowing in the organic EL device can be reduced with increasing aperture ratio, and accordingly the lifetime of the display apparatus can be increased. The display apparatus of one embodiment of the present invention can have a higher aperture ratio and thus can have higher display quality. Furthermore, the display apparatus of one embodiment of the present invention has excellent effect that the reliability (especially the lifetime) can be significantly improved with increasing aperture ratio.

In the case where the light-emitting layer is processed into an island shape, a layer located below the light-emitting layer (e.g., a carrier-injection layer or a carrier-transport layer, more specifically, a hole-injection layer, a hole-transport layer, or the like) is preferably processed into an island shape with the same pattern as the light-emitting layer. Processing a layer located below the light-emitting layer into an island shape with the same pattern as the light-emitting layer can reduce a leakage current (sometimes referred to as a horizontal-direction leakage current, a horizontal leakage current, or a lateral leakage current) that might be generated between adjacent subpixels. For example, in the case where a hole-injection layer is shared by adjacent subpixels, a horizontal leakage current might be generated due to the hole-injection layer. In contrast, in the display apparatus of one embodiment of the present invention, the hole-injection layer can be processed into an island shape with the same pattern as the light-emitting layer; hence, a horizontal leakage current between adjacent subpixels is not substantially generated or a horizontal leakage current can be extremely small.

Furthermore, a pattern (also referred to as a processing size) of the EL layer itself can be made much smaller than that in the case of using a metal mask. For example, in the case of using a metal mask for forming EL layers separately, a variation in the thickness occurs between the center and the edge of the EL layer. This causes a reduction in an effective area that can be used as a light-emitting region with respect to the area of the EL layer. In contrast, in the above manufacturing method, a film deposited to have a uniform thickness is processed, so that island-shaped EL layers can be formed to have a uniform thickness. Accordingly, even in a fine pattern, almost the whole area can be used as a light-emitting region. Consequently, a display apparatus having both high resolution and a high aperture ratio can be manufactured.

In addition, in a method for manufacturing a display apparatus of one embodiment of the present invention, it is preferable that a layer including a light-emitting layer (that can be referred to as an EL layer or part of an EL layer) be formed over the entire surface, and then a mask layer be formed over the EL layer. Next, it is preferable that a resist mask be formed over the mask layer, and the EL layer and the mask layer be processed using the resist mask, whereby an island-shaped EL layer be formed.

Provision of a mask layer over an EL layer can reduce damage to the EL layer during a manufacturing step of the display apparatus and increase the reliability of the light-emitting device.

Each of the first layer and the second layer described above includes at least a light-emitting layer and preferably consists of a plurality of layers. Specifically, each of the first layer and the second layer preferably includes one or more layers over the light-emitting layer. A layer included between the light-emitting layer and the mask layer can inhibit the light-emitting layer from being exposed on the outermost surface during the manufacturing steps of the display apparatus and can reduce damage to the light-emitting layer. Thus, the reliability of the light-emitting device can be increased. Thus, the first layer and the second layer each preferably include the light-emitting layer and a carrier-blocking layer (a hole-blocking layer or an electron-blocking layer) or a carrier-transport layer (an electron-transport layer or a hole-transport layer) over the light-emitting layer.

Note that it is not necessary to form all layers included in the EL layers separately for the respective light-emitting devices emitting light of different colors, and some layers of the EL layers can be deposited in the same step. Examples of layers in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In the method for manufacturing a display apparatus of one embodiment of the present invention, after some layers included in the EL layer are formed into an island shape separately for each color, the mask layer is at least partly removed; then, the other remaining layers included in the EL layers and a common electrode (also referred to as an upper electrode) are formed (as a single film) so as to be shared by the light-emitting devices of different colors. For example, a carrier-injection layer and a common electrode can be formed so as to be shared by the light-emitting devices of the respective colors.

Meanwhile, the carrier-injection layer is often a layer having relatively high conductivity in the EL layer. Thus, when the carrier-injection layer is in contact with the side surface of any layer of the EL layer formed into an island shape or the side surface of the pixel electrode, the light-emitting device might be short-circuited. Note that also in the case where the carrier-injection layer is provided in an island shape and the common electrode is formed to be shared by the light-emitting devices of different colors, the light-emitting device might be short-circuited when the common electrode is in contact with the side surface of the EL layer or the side surface of the pixel electrode.

In view of the above, the display apparatus of one embodiment of the present invention includes an insulating layer that covers at least the side surface of the island-shaped light-emitting layer. Note that the side surface of the island-shaped light-emitting layer here refers to the plane that is not parallel to the substrate (or the surface where the light-emitting layer is formed) among the interfaces between the island-shaped light-emitting layer and other layers. The side surface is not necessarily one of a planar plane and a curved plane in an exactly mathematical perspective.

This can inhibit at least some layers of the island-shaped EL layers and the pixel electrodes from being in contact with the carrier-injection layer or the common electrode. Hence, a short circuit of the light-emitting device is inhibited, and the reliability of the light-emitting device can be increased.

In addition, the insulating layer preferably has a function of a barrier insulating layer against at least one of water and oxygen. Alternatively, the insulating layer preferably has a function of inhibiting the diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

When the insulating layer has a function of the barrier insulating layer or a gettering function, entry of impurities (typically, at least one of water and oxygen) that would diffuse into the light-emitting devices from the outside can be inhibited. With this structure, a highly reliable light-emitting device, furthermore, a highly reliable display apparatus can be provided.

The display apparatus of one embodiment of the present invention includes a pixel electrode functioning as an anode; an island-shaped hole-injection layer, an island-shaped hole-transport layer, an island-shaped light-emitting layer, an island-shaped hole-blocking layer, and an island-shaped electron-transport layer that are provided in this order over the pixel electrode; an insulating layer provided to cover the side surfaces of the hole-injection layer, the hole-transport layer, the light-emitting layer, the hole-blocking layer, and the electron-transport layer; an electron-injection layer provided over the electron-transport layer; and a common electrode that is provided over the electron-injection layer and functions as a cathode.

Alternatively, the display apparatus of one embodiment of the present invention includes a pixel electrode functioning as a cathode; an island-shaped electron-injection layer, an island-shaped electron-transport layer, an island-shaped light-emitting layer, an island-shaped electron-blocking layer, and an island-shaped hole-transport layer that are provided in this order over the pixel electrode; an insulating layer provided to cover the side surfaces of the electron-injection layer, the electron-transport layer, the light-emitting layer, the electron-blocking layer, and the hole-transport layer; a hole-injection layer provided over the hole-transport layer; and a common electrode that is provided over the hole-injection layer and functions as an anode.

The hole-injection layer, the electron-injection layer and the like is often a layer having relatively high conductivity in the EL layer. Since the side surfaces of these layers are covered with the insulating layer in the display apparatus of one embodiment of the present invention, these layers can be inhibited from being in contact with the common electrode or the like. Hence, a short circuit of the light-emitting device is inhibited, and the reliability of the light-emitting device can be increased.

The insulating layer that covers the side surface of the island-shaped EL layer may have a single-layer structure or a stacked-layer structure.

For example, an insulating layer having a single-layer structure using an inorganic material can be used for a protective insulating layer for the EL layer. This leads to higher reliability of the display apparatus.

In the case where the insulating layer having a stacked-layer structure is used, the first layer of the insulating layer is preferably formed using an inorganic insulating material because it is formed in contact with the EL layer. In particular, the first layer is preferably formed by an atomic layer deposition (ALD) method, by which damage due to deposition is small. Alternatively, an inorganic insulating layer is preferably formed by a sputtering method, a chemical vapor deposition (CVD) method, or a plasma-enhanced chemical vapor deposition (PECVD) method, which have higher deposition speed than an ALD method. In that case, a highly reliable display apparatus can be manufactured with high productivity. The second layer of the insulating layer is preferably formed using an organic material to fill a concave portion formed in the first layer of the insulating layer.

For example, an aluminum oxide film formed by an ALD method can be used as the first layer of the insulating layer, and an organic resin film can be used as the second layer of the insulating layer.

In the case where the side surface of the EL layer and the organic resin film are in direct contact with each other, the EL layer might be damaged by an organic solvent or the like that might be contained in the organic resin film. When an inorganic insulating film such as an aluminum oxide film formed by an ALD method is used as the first layer of the insulating layer, a structure can be employed in which the organic resin film and the side surface of the EL layer are not in direct contact with each other. Thus, the EL layer can be inhibited from being dissolved by the organic solvent, for example.

The display apparatus of one embodiment of the present invention includes a touch sensor that acquires the positional data of an object being in contact with or in proximity to a display surface. As the touch sensor, any of various types such as a resistive type, a capacitive type, an infrared type, an electromagnetic induction type, and a surface acoustic wave type can be employed. As the touch sensor, a capacitive touch sensor is particularly preferable.

Examples of the capacitive touch sensor include a surface capacitive touch sensor and a projected capacitive touch sensor. Examples of the projected capacitive type include a self-capacitive type and a mutual capacitive type. The use of a mutual capacitive type is preferable because multiple points can be sensed simultaneously.

The mutual capacitive touch sensor can include a plurality of electrodes to which pulse potentials are supplied and a plurality of electrodes to which a sensor circuit is connected. The touch sensor can sense the approach of a finger or the like using a change in capacitance between the electrodes. The electrodes included in the touch sensor are preferably placed closer to a display surface side than the light-emitting device is.

At least part of an electrode of the touch sensor overlaps with a region interposed between two adjacent light-emitting devices or a region interposed between two adjacent EL layers. Furthermore, at least part of the electrode of the touch sensor preferably includes a region overlapping with the organic resin film provided between two adjacent EL layers. With such a structure, the touch sensor can be provided in an upper portion of the display apparatus without reducing the light-emitting area of the light-emitting device. Thus, a display apparatus having both a high aperture ratio and a high resolution can be provided.

Here, a metal or an alloy material is preferably used for the conductive layer functioning as the electrode of the touch sensor. When the electrode of the touch sensor is placed as described above, a metal or an alloy material that does not have a light-transmitting property can be used as the electrode of the touch sensor without reducing the aperture ratio of the display apparatus. When a metal or an alloy material with low resistance is used for the electrode of the touch sensor, touch sensing with high sensitivity can be achieved.

Note that a light-transmitting electrode that transmits light emitted from the light-emitting element can be used as the electrode of the touch sensor. Here, the light-transmitting electrode can be provided to overlap with the light-emitting device.

The light-emitting device can be provided between a pair of substrates. As the substrate, a rigid substrate such as a glass substrate or a flexible film may be used. In this case, the electrode of the touch sensor can be formed over the substrate located on the display surface side. Alternatively, the structure in which the electrode of the touch sensor is formed over another substrate and bonded to the display surface side may be employed.

The electrode of the touch sensor is preferably placed between the pair of substrates. Here, a protective layer that covers the light-emitting device can be provided, and the electrode of the touch sensor can be provided over the protective layer. Thus, the number of components can be reduced, whereby the manufacturing steps can be simplified. Furthermore, since the thickness of the display apparatus can be made small, the structure is particularly suitable in the case where a display apparatus is used as a flexible display using a flexible film for the substrate.

### [Structure Example 1 of Display Apparatus]

FIG. 1 to FIG. 9 each illustrate a display apparatus of one embodiment of the present invention.

FIG. 1A illustrates a top view of a display apparatus 100. The display apparatus 100 includes a display portion in which a plurality of pixels 110 are arranged and a connection portion 140 outside the display portion. A plurality of subpixels are arranged in a matrix in the display portion. FIG. 1A illustrates subpixels arranged in two rows and six columns, which form pixels in two rows and two columns. The connection portion 140 can also be referred to as a cathode contact portion.

The pixel 110 illustrated in FIG. 1A employs stripe arrangement. Each of the pixels 110 illustrated in FIG. 1A is made up of three subpixels 110a, 110b, and 110c. The subpixels 110a, 110b, and 110c include light-emitting devices that emit light of different colors. As the subpixels 110a, 110b, and 110c, subpixels of three colors of red (R), green (G), and blue (B) and subpixels of three colors of yellow (Y), cyan (C), and magenta (M) can be given, for example. The number of types of subpixels is not limited to three, and four or more types of subpixels may be used. As the four subpixels, subpixels of four colors of R, G, B, and white (W), subpixels of four colors of R, G, B, and Y, or four subpixels of R, G, B, and infrared light (IR) can be given, for example.

In this specification and the like, the row direction and the column direction are sometimes referred to as the X direction and the Y direction, respectively. The X direction and the Y direction intersect with each other and are, for example, orthogonal to each other (see FIG. 1A).

FIG. 1A illustrates an example in which subpixels of different colors are arranged in the X direction and subpixels of the same color are arranged in the Y direction.

Although the top view of FIG. 1A illustrates an example in which the connection portion 140 is located in the lower side of the display portion, one embodiment of the present invention is not limited thereto. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

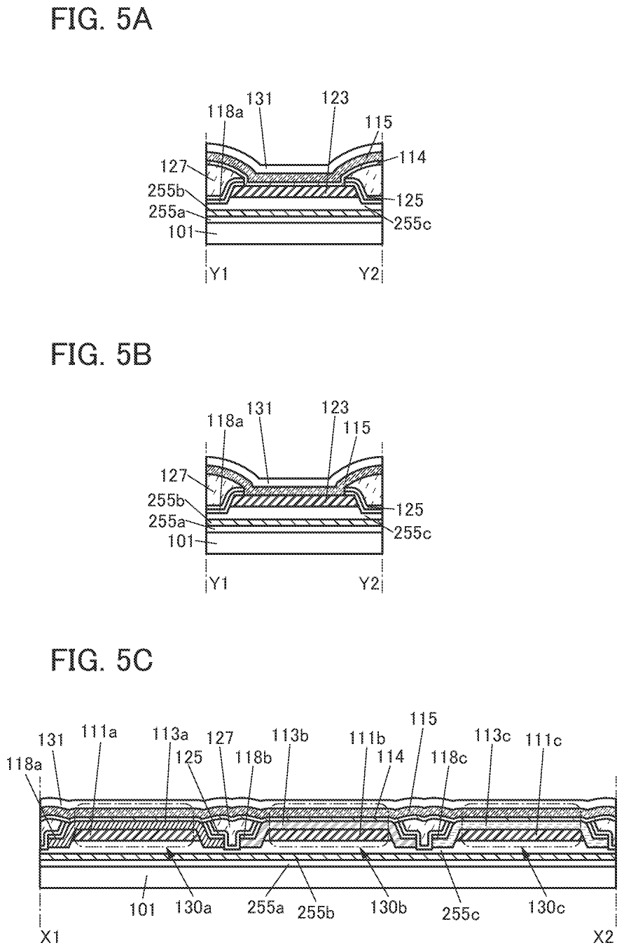

FIG. 1B and FIG. 5C each illustrate a cross-sectional view taken along the dashed-dotted line X1-X2 in FIG. 1A. In the display apparatus 100, a layer including transistors is provided over a substrate 101, insulating layers 255a, 255b, and 255c are provided over the layer including transistors, light-emitting devices 130a, 130b, and 130c are provided over the insulating layers 255a, 255b, and 255c, and a protective layer 131 is provided to cover these light-emitting devices. In a region between adjacent light-emitting devices, an insulating layer 125 and an insulating layer 127 over the insulating layer 125 are provided. Note that in the description below, the light-emitting devices 130a, 130b, and 130c are collectively referred to as a light-emitting device 130 in some cases.

Although FIG. 1B and the like illustrate a plurality of cross sections of the insulating layer 125 and the insulating layer 127, the insulating layer 125 and the insulating layer 127 are each a continuous layer when the display apparatus 100 is seen from above. In other words, the display apparatus 100 can have a structure in which one insulating layer 125 and one insulating layer 127 are included, for example. Note that the display apparatus 100 may include a plurality of insulating layers 125 which are separated from each other and a plurality of insulating layers 127 which are separated from each other.

As illustrated in FIG. 1B, in the display apparatus 100, a resin layer 147, an insulating layer 103, a conductive layer 104, an insulating layer 105, a conductive layer 106, an adhesive layer 107, and a substrate 102 are provided over the protective layer 131. In the substrate 101 side of the display apparatus 100 illustrated in FIG. 1B, the resin layer 147 is provided over the protective layer 131, the insulating layer 103 is provided over the resin layer 147, the conductive layer 104 is provided over the insulating layer 103, the insulating layer 105 is provided over the insulating layer 103 and the conductive layer 104, and the conductive layer 106 is provided over the insulating layer 105. The substrate 102 is bonded to the substrate 101 with the adhesive layer 107. Here, the adhesive layer 107 is in contact with the conductive layer 106, the insulating layer 105, and the substrate 102.

The conductive layer 104 and the conductive layer 106 function as the electrodes of the touch sensor. In the case of using a mutual capacitive type as a type of the touch sensor, a pulse potential may be supplied to one of the conductive layer 104 and the conductive layer 106, and an analog-digital (A/D) conversion circuit or a detection circuit such as a sense amplifier may be electrically connected to the other of the conductive layer 104 and the conductive layer 106, for example. In that case, capacitance is formed between the conductive layer 104 and the conductive layer 106. When the finger or the like approaches, the capacitance changes (specifically, the capacitance is reduced). This change in the capacitance appears, when a pulse potential is supplied to one of the conductive layer 104 and the conductive layer 106, as a change in the amplitude of a signal that occurs in the other of the conductive layer 104 and the conductive layer 106. Accordingly, the touch and proximity of the finger or the like can be detected.

Note that one of the conductive layer 104 and the conductive layer 106 may function as both of the electrodes of the touch sensor, and the other of the conductive layer 104 and the conductive layer 106 may function as a connection portion of the electrodes of the touch sensor. In this case, as illustrated in FIG. 1B, a portion where the conductive layer 104 and the conductive layer 106 are in contact with each other with an opening formed in the insulating layer 105 therebetween is formed.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

A layer including a transistor over an upper portion of the substrate 101 can employ a stacked-layer structure in which a plurality of transistors are provided over a substrate and an insulating layer is provided to cover these transistors, for example. The insulating layer over the transistors may have a single-layer structure or a stacked-layer structure. In FIG. 1B and the like, the insulating layer 255a, the insulating layer 255b over the insulating layer 255a, and the insulating layer 255c over the insulating layer 255b are illustrated as the insulating layers over the transistors. These insulating layers may have a concave portion between adjacent light-emitting devices. In the example illustrated in FIG. 1B and the like, the insulating layer 255c has a concave portion.

As each of the insulating layer 255a, the insulating layer 255b, and the insulating layer 255c, a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. More specifically, it is preferred that a silicon oxide film be used as the insulating layer 255a and the insulating layer 255c, and a silicon nitride film be used as the insulating layer 255b. The insulating layer 255b preferably has a function of an etching protective film.

Note that in this specification and the like, oxynitride refers to a material that contains more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition.

Structure examples of the layer including a transistor in the upper portion of the substrate 101 will be described in Embodiment 4 and Embodiment 5.

The light-emitting devices 130a, 130b, and 130c emit light of different colors. Preferably, the light-emitting devices 130a, 130b, and 130c are a combination of light-emitting devices emitting light of three colors, red (R), green (G), and blue (B), for example.

As the light-emitting devices 130a, 130b, and 130c, a light-emitting device such as an OLED (Organic Light Emitting Diode) or a QLED (Quantum-dot Light Emitting Diode) is preferably used. Examples of a light-emitting substance contained in the light-emitting device include a substance that emits fluorescent light (a fluorescent material), a substance that emits phosphorescent light (a phosphorescent material), an inorganic compound (a quantum dot material and the like), and a substance that exhibits thermally activated delayed fluorescence (a thermally activated delayed fluorescent (TADF) material). As the TADF material, a material in which the singlet excited state and the triplet excited state are in thermal equilibrium may be used. Since such a TADF material has a short emission lifetime (excitation lifetime), it inhibits a reduction in the emission efficiency of a light-emitting device in a high-luminance region.

The light-emitting device includes an EL layer between a pair of electrodes. The EL layer includes at least a light-emitting layer. In this specification and the like, one of the pair of electrodes may be referred to as a pixel electrode and the other may be referred to as a common electrode.

One of the pair of electrodes of the light-emitting device functions as an anode and the other electrode functions as a cathode. The case where the pixel electrode functions as an anode and the common electrode functions as a cathode is described below as an example in some cases.

Each of end portions of a pixel electrode 111a, a pixel electrode 111b, and a pixel electrode 111c preferably has a tapered shape. When the end portions of these pixel electrodes have a tapered shape, the tapered shape is also reflected in first layers 113a, second layers 113b, and third layers 113c provided along the side surfaces of the pixel electrodes. When the side surfaces of the pixel electrodes are tapered, coverage with EL layers provided along the side surfaces of the pixel electrodes can be improved. The pixel electrodes having tapered side surfaces are preferred because a foreign matter (such as dust or particles) mixed during the manufacturing process can be easily removed by treatment such as cleaning.

Note that in this specification and the like, a tapered shape refers to a shape such that at least part of a side surface of a component is inclined with respect to the substrate surface. For example, a tapered shape preferably includes a region where the angle formed by the inclined side surface and the substrate surface (such an angle is also referred to as a taper angle) is less than 90°.

The light-emitting device 130a includes the pixel electrode 111a over the insulating layer 255c, the island-shaped first layer 113a over the pixel electrode 111a, a common layer 114 over the island-shaped first layer 113a, and a common electrode 115 over the common layer 114. In the light-emitting device 130a, the first layer 113a and the common layer 114 can be collectively referred to as an EL layer.

The light-emitting device 130b includes the pixel electrode 111b over the insulating layer 255c, the island-shaped second layer 113b over the pixel electrode 111b, the common layer 114 over the island-shaped second layer 113b, and the common electrode 115 over the common layer 114. In the light-emitting device 130b, the second layer 113b and the common layer 114 can be collectively referred to as an EL layer.

The light-emitting device 130c includes the pixel electrode 111c over the insulating layer 255c, the island-shaped third layer 113c over the pixel electrode 111c, the common layer 114 over the island-shaped third layer 113c, and the common electrode 115 over the common layer 114. In the light-emitting device 130c, the third layer 113c and the common layer 114 can be collectively referred to as an EL layer.

There is no particular limitation on the structure of the light-emitting device in this embodiment, and the light-emitting device can have a single structure or a tandem structure.

In this embodiment, the island-shaped layers provided in the EL layers included in the light-emitting devices are referred to as the first layer 113a, the second layer 113b, and the third layer 113c, and the layer shared by the plurality of light-emitting devices is referred to as the common layer 114.

Each of the first layer 113a, the second layer 113b, and the third layer 113c is processed into an island shape by a photolithography method. Thus, each end portion of the first layer 113a, the second layer 113b, and the third layer 113c has a shape such that an angle formed by the top surface and the side surface is close to 90°. On the other hand, an organic film formed using an FMM (Fine Metal Mask) or the like tends to be gradually thinner in a portion closer to the end portion. For example, since the organic film is formed to have a sloped top surface shape in the range greater than or equal to 1 μm and less than or equal to 10 μm in the vicinity of the end portion, the top surface and the side surface are difficult to distinguish from each other.

The top surface and the side surface of each of the first layer 113a, the second layer 113b, and the third layer 113c are clearly distinguished from each other. Accordingly, regarding the first layer 113a and the second layer 113b which are adjacent to each other, one of the side surfaces of the first layer 113a and one of the side surfaces of the second layer 113b are placed to face each other. Similarly, regarding the first layer 113a and the third layer 113c which are adjacent to each other, one of the side surfaces of the first layer 113a and one of the side surfaces of the third layer 113c are placed to face each other and regarding the second layer 113b and the third layer 113c which are adjacent to each other, one of the side surfaces of the second layer 113b and one of the side surfaces of the third layer 113c are placed to face each other.

The first layer 113a, the second layer 113b, and the third layer 113c each at least include a light-emitting layer. Preferably, the first layer 113a, the second layer 113b, and the third layer 113c include a red-light-emitting layer, a green-light-emitting layer, and a blue-light-emitting layer, respectively, for example.

Each of the first layer 113a, the second layer 113b, and the third layer 113c may include one or more of a hole-injection layer, a hole-transport layer, a hole-blocking layer, a charge-generation layer, an electron-blocking layer, an electron-transport layer, and an electron-injection layer.

For example, the first layer 113a, the second layer 113b, and the third layer 113c may each include a hole-injection layer, a hole-transport layer, a light-emitting layer, and an electron-transport layer. In addition, an electron-blocking layer may be provided between the hole-transport layer and the light-emitting layer. Furthermore, an electron-injection layer may be provided over the electron-transport layer.

The first layer 113a, the second layer 113b, and the third layer 113c may each include an electron-injection layer, an electron-transport layer, a light-emitting layer, and a hole-transport layer in this order, for example. In addition, a hole-blocking layer may be provided between the electron-transport layer and the light-emitting layer. Furthermore, a hole-injection layer may be provided over the hole-transport layer.

The first layer 113a, the second layer 113b, and the third layer 113c each preferably include a light-emitting layer and a carrier-transport layer (an electron-transport layer or a hole-transport layer) over the light-emitting layer. Since the surfaces of the first layer 113a, the second layer 113b, and the third layer 113c are exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The first layer 113a, the second layer 113b, and the third layer 113c include a first light-emitting unit, a charge-generation layer, and a second light-emitting unit, for example. Preferably, the first layer 113a, the second layer 113b, and the third layer 113c include two or more light-emitting units that emit red light, two or more light-emitting units that emit green light, and two or more light-emitting units that emit blue light, for example.

The second light-emitting unit preferably includes a light-emitting layer and a carrier-transport layer (an electron-transport layer or a hole-transport layer) over the light-emitting layer. Since the surface of the second light-emitting unit is exposed in the manufacturing process of the display apparatus, providing the carrier-transport layer over the light-emitting layer inhibits the light-emitting layer from being exposed on the outermost surface, so that damage to the light-emitting layer can be reduced. Thus, the reliability of the light-emitting device can be increased.

The common layer 114 includes, for example, an electron-injection layer or a hole-injection layer. Alternatively, the common layer 114 may include a stack of an electron-transport layer and an electron-injection layer, and may include a stack of a hole-transport layer and a hole-injection layer. The common layer 114 is shared by the light-emitting devices 130a, 130b, and 130c.

The common electrode 115 is shared by the light-emitting devices 130a, 130b, and 130c. As illustrated in FIG. 5A and FIG. 5B, the common electrode 115 shared by the plurality of light-emitting devices is electrically connected to a conductive layer 123 provided in the connection portion 140. Here, FIG. 5A and FIG. 5B are cross-sectional views along the dashed-dotted line Y1-Y2 in FIG. 1A. Although the structure above the protective layer 131 is not illustrated in FIG. 5A and FIG. 5B, at least one or more of the resin layer 147, the insulating layer 103, the conductive layer 104, the insulating layer 105, the conductive layer 106, the adhesive layer 107, and the substrate 102 can be provided as appropriate. Alternatively, as the conductive layer 123, a conductive layer formed using the same material in the same step as the pixel electrode 111 is preferably used.

Note that FIG. 5A illustrates an example in which the common layer 114 is provided over the conductive layer 123 and the conductive layer 123 and the common electrode 115 are electrically connected to each other through the common layer 114. The common layer 114 is not necessarily provided in the connection portion 140. In FIG. 5B, the conductive layer 123 and the common electrode 115 are directly connected to each other. For example, by using a mask for specifying a film formation area (also referred to as an area mask or a rough metal mask to be distinguished from a fine metal mask), the common layer 114 can be formed in a region different from a region where the common electrode 115 is formed.

The protective layer 131 is preferably included over the light-emitting devices 130a, 130b, and 130c. Providing the protective layer 131 can improve the reliability of the light-emitting device. The protective layer 131 may have a single-layer structure or a stacked-layer structure of two or more layers.

There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting device by inhibiting oxidation of the common electrode 115 and inhibiting entry of impurities (e.g., moisture and oxygen) into the light-emitting device, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are each inorganic materials having a high visible-light-transmitting property.

The protective layer 131 can be, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layers side.

Furthermore, the protective layer 131 may include an organic film. For example, the protective layer 131 may include both an organic film and an inorganic film. Examples of an organic material that can be used for the protective layer 131 include organic insulating materials that can be used for an insulating layer 121 described later.

The protective layer 131 may have a stacked-layer structure of two layers which are formed by different formation methods. Specifically, the first layer of the protective layer 131 may be formed by an ALD method, and the second layer of the protective layer 131 may be formed by a sputtering method.

In FIG. 1B and the like, an insulating layer covering an end portion of the top surface of the pixel electrode 111a is not provided between the pixel electrode 111a and the first layer 113a. An insulating layer covering an end portion of the top surface of the pixel electrode 111b is not provided between the pixel electrode 111b and the second layer 113b. An insulating layer covering an end portion of the top surface of the pixel electrode 111c is not provided between the pixel electrode 111c and the third layer 113c. Thus, the distance between adjacent light-emitting devices can be extremely shortened. Accordingly, the display apparatus can have high resolution or high definition.

In FIG. 1B and the like, a mask layer 118a is located over the first layer 113a included in the light-emitting device 130a, a mask layer 118b is located over the second layer 113b included in the light-emitting device 130b, and a mask layer 118c is located over the third layer 113c included in the light-emitting device 130c. The mask layer 118a is a remaining part of a mask layer provided over the top surface of the first layer 113a at the time of processing the first layer 113a. Similarly, the mask layer 118b and the mask layer 118c are remaining parts of the mask layers provided at the time of forming the second layer 113b and the third layer 113c, respectively. Thus, the mask layer used to protect the EL layer in manufacture of the display apparatus may partly remain in the display apparatus of one embodiment of the present invention. For any two or all of the mask layer 118a to the mask layer 118c, the same or different materials may be used. Note that hereinafter the mask layer 118a, the mask layer 118b, and the mask layer 118c may be collectively referred to as a mask layer 118.

In FIG. 1B, one end portion of the mask layer 118a is aligned or substantially aligned with the end portion of the first layer 113a, and the other end portion of the mask layer 118a is located over the first layer 113a. Here, the other end portion of the mask layer 118a preferably overlaps with the first layer 113a and the pixel electrode 111a. In that case, the other end portion of the mask layer 118a is likely to be formed on the substantially planar surface of the first layer 113a. The same applies to the mask layer 118b and the mask layer 118c. The mask layer 118 remains between, for example, the EL layer processed into an island shape (the first layer 113a, the second layer 113b, or the third layer 113c) and the insulating layer 125 in some cases.

As the mask layer 118, one or more kinds of inorganic films such as a metal film, an alloy film, a metal oxide film, a semiconductor film, an organic insulating film, and an inorganic insulating film can be used, for example. As the mask layer 118, a variety of inorganic insulating films that can be used as the protective layer 131 can be used. For example, an inorganic insulating material such as aluminum oxide, hafnium oxide, or silicon oxide can be used.

There is no particular limitation on which is larger, the width of the pixel electrode or the width of the island-shaped EL layer. The pixel electrode 111a and the first layer 113a are given as examples in the description below. The following description also applies to the pixel electrode 111b and the second layer 113b, and the pixel electrode 111c and the third layer 113c.

FIG. 1B and the like illustrate an example where the end portion of the first layer 113a is located outward from the end portion of the pixel electrode 111a. In FIG. 1B and the like, the first layer 113a is formed to cover the end portion of the pixel electrode 111a. Such a structure can increase an aperture ratio as compared with the structure in which the end portion of the island-shaped EL layer is located inward from the end portion of the pixel electrode.

Covering the side surface of the pixel electrode with the EL layer can inhibit contact between the pixel electrode and the common electrode 115 (or the common layer 114); thus, a short circuit in the light-emitting device can be inhibited. Furthermore, the distance between the light-emitting region (i.e., the region overlapping with the pixel electrode) in the EL layer and the end portion of the EL layer can be increased. The end portion of the first layer 113a, the end portion of the second layer 113b, and the end portion of the third layer 113c include a portion that may be damaged in the manufacturing process of the display apparatus. By avoiding the use of the portion for the light-emitting region, variation in characteristics of the light-emitting device can be inhibited, and the reliability can be increased.

As illustrated in FIG. 1B, the side surfaces of the first layer 113a, the second layer 113b, and the third layer 113c are covered with the insulating layer 127 and the insulating layer 125. Part of the top surfaces of the first layer 113a, the second layer 113b, and the third layer 113c is covered with the insulating layer 127, the insulating layer 125, and the mask layer 118.

The insulating layer 125 preferably covers at least one of the side surfaces of the island-shaped EL layers, and further preferably covers both of the side surfaces of the island-shaped EL layers. The insulating layer 125 can be in contact with the side surface of each island-shaped EL layers.

In FIG. 1B and the like, the end portion of the pixel electrode 111a is covered with the first layer 113a and the insulating layer 125 is in contact with the side surface of the first layer 113a. Similarly, the end portion of the pixel electrode 111b is covered with the second layer 113b, the end portion of the pixel electrode 111c is covered with the third layer 113c, and the insulating layer 125 is in contact with the side surface of the second layer 113b and the side surface of the third layer 113c.

With the above-described structure, the common layer 114 (or the common electrode 115) can be inhibited from being in contact with the side surfaces of the pixel electrodes 111a, 111b, and 111c, the first layer 113a, the second layer 113b, and the third layer 113c, whereby a short circuit of the light-emitting device can be inhibited. Thus, the reliability of the light-emitting device can be increased.

The insulating layer 127 is provided over the insulating layer 125 to fill a concave portion in the insulating layer 125. The insulating layer 127 can overlap with part of the top surfaces or the side surfaces of the first layer 113a, the second layer 113b, and the third layer 113c (in other words, the insulating layer 127 can cover the side surfaces) with the insulating layer 125 therebetween.

The insulating layer 125 and the insulating layer 127 can fill a space between adjacent island-shaped layers, whereby unevenness with a big level difference of the formation surfaces of the layers (e.g., the carrier-injection layer and the common electrode) provided over the island-shaped layers can be reduced and the formation surfaces can be more planar. Thus, the coverage with the carrier-injection layer, the common electrode, and the like can be increased and disconnection of the carrier-injection layer, the common electrode, and the like can be inhibited.

The common layer 114 and the common electrode 115 are provided over the first layer 113a, the second layer 113b, the third layer 113c, the mask layer 118, the insulating layer 125, and the insulating layer 127. At the stage before the insulating layer 125 and the insulating layer 127 are provided, a step due to a region where the pixel electrode and the EL layer are provided and a region where the pixel electrode and the EL layer are not provided (a region between the light-emitting devices) is caused. In the display panel of one embodiment of the present invention, the step can be reduced by including the insulating layer 125 and the insulating layer 127, and the coverage with the common layer 114 and the common electrode 115 can be improved. Consequently, it is possible to inhibit a connection defect due to disconnection. Alternatively, an increase in electrical resistance, which is caused by a reduction in thickness of the common electrode 115 locally due to the step, can be inhibited.

The top surface of the insulating layer 127 preferably has a shape with higher planarity and may have a convex portion, a convex surface, a concave surface, or a concave portion. For example, the top surface of the insulating layer 127 preferably has a smooth convex shape with high planarity.

The insulating layer 125 can be provided in contact with the island-shaped EL layer. Thus, peeling of the island-shaped EL layer can be prevented. When the insulating layer and the island-shaped EL layer are in close contact with each other, an effect of fixing adjacent island-shaped EL layers by or attaching the adjacent island-shaped EL layers to the insulating layer can be attained. Thus, the reliability of the light-emitting device can be increased. The manufacturing yield of the light-emitting device can be increased.

Here, the insulating layer 125 has a region in contact with the side surface of the island-shaped EL layer and functions as a protective insulating layer of the EL layer. With the insulating layer 125, entry of impurities (such as oxygen and moisture) from the side surface of the island-shaped EL layer into its inside can be inhibited, and thus a highly reliable display panel can be obtained.

Next, an example of a material and formation method for the insulating layer 125 and the insulating layer 127 is described.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 to be described later is formed. An inorganic insulating film such as an aluminum oxide film, a hafnium oxide film, or a silicon oxide film is formed by an ALD method as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting the diffusion of at least one of water and oxygen. The insulating layer 125 preferably has a function of capturing or fixing (also referred to as gettering) at least one of water and oxygen.

When the insulating layer 125 has a function of the barrier insulating layer or a gettering function, entry of impurities (typically, at least one of water and oxygen) that would diffuse into the light-emitting devices from the outside can be inhibited. With this structure, a highly reliable light-emitting device, and furthermore, a highly reliable display panel can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 125 can be formed by a sputtering method, a CVD method, a pulsed laser deposition (PLD) method, an ALD method, or the like. The insulating layer 125 is preferably formed by an ALD method achieving good coverage.

When the substrate temperature at the time when the insulating layer 125 is formed is increased, the formed insulating layer 125, even with a small thickness, can have a low impurity concentration and a high barrier property against at least one of water and oxygen. Thus, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of an island-shaped EL layer, and it is preferable that the insulating layer 125 be formed at a temperature lower than the upper temperature limit of the EL layer. Thus, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the upper temperature limit are the glass transition point, the softening point, the melting point, the thermal decomposition temperature, and the 5% weight loss temperature. The upper temperature limit of the EL layer can be, for example, any of the above temperatures, preferably the lowest temperature thereof.

As the insulating layer 125, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating layer 127 provided over the insulating layer 125 has a function of reducing unevenness with a big level difference of the insulating layer 125 formed between adjacent light-emitting devices. In other words, the insulating layer 127 brings an effect of improving the planarity of the surface where the common electrode 115 is formed.

As the insulating layer 127, an insulating layer containing an organic material can be suitably used. As the organic material, a photosensitive organic resin is preferably used; for example, a photosensitive resin composite containing an acrylic resin is used. The viscosity of the material of the insulating layer 127 is greater than or equal to 1 cP and less than or equal to 1500 cP, and is preferably greater than or equal to 1 cP and less than or equal to 12 cP. By setting the viscosity of the material of the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material usable for the insulating layer 127 is not limited to the above as long as the insulating layer 127 has the tapered side surface as described later. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used in some cases, for example. Alternatively, an organic material such as polyvinyl alcohol (PVA), polyvinylbutyral, polyvinylpyrrolidone, polyethylene glycol, polyglycerin, pullulan, water-soluble cellulose, an alcohol-soluble polyamide resin, or the like can be used for the insulating layer 127 in some cases. As the photosensitive resin, a photoresist can be used in some cases. As the photosensitive resin, a positive material or a negative material can be used in some cases.

The insulating layer 127 may be formed using a material absorbing visible light. When the insulating layer 127 absorbs light emitted by the light-emitting device, leakage of light (stray light) from the light-emitting device to an adjacent light-emitting device through the insulating layer 127 can be inhibited. Thus, the display quality of the display panel can be improved. Since the display quality of the display panel can be improved without using a polarizing plate, the weight and thickness of the display panel can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, a doctor blade coating method, slit coating, roll coating, curtain coating, or knife coating. Specifically, the insulating layer 127 is preferably formed by spin coating.

In addition, the insulating layer 127 is formed at a temperature lower than the upper temperature limit of the EL layer. The typical substrate temperature in the formation of the layer 127 is lower than or equal to 200° C., preferably lower than or equal to 180° C., further preferably lower than or equal to 160° C., still further preferably lower than or equal to 150° C., yet still further preferably lower than or equal to 140° C.

An example of the structure of the insulating layer 127 and the like is described below using the structure of the insulating layer 127 between the light-emitting device 130a and the light-emitting device 130b as an example. Note that the same applies to the insulating layer 127 between the light-emitting device 130b and the light-emitting device 130c, the insulating layer 127 between the light-emitting device 130c and the light-emitting device 130a, and the like. Although the end portion of the insulating layer 127 over the second layer 113b is described below as an example in some cases, the same applies to the end portion of the insulating layer 127 over the first layer 113a, the end portion of the insulating layer 127 over the third layer 113c, and the like.

The insulating layer 127 preferably has the tapered side surface with a taper angle θ1 in the cross-sectional view of the display apparatus. The taper angle θ1 is an angle formed by the side surface of the insulating layer 127 and the substrate surface. Note that the taper angle θ1 is not limited to the angle with the substrate surface, and may be an angle formed by the side surface of the insulating layer 127 and the top surface of a planar portion of the insulating layer 125, the top surface of a planar portion of the second layer 113b, the top surface of a planar portion of the pixel electrode 111b, or the like. Note that in this specification and the like, as illustrated in FIG. 1B, the side surface of the insulating layer 127 may sometimes refer to the side surface of a portion having a convex shape above planar portion of the first layer 113a, the second layer 113b, or the third layer 113c.

The taper angle θ1 of the insulating layer 127 is less than 90°, preferably less than or equal to 60°, and further preferably less than or equal to 45°. Such a forward tapered shape of the end portion of the side surface of the insulating layer 127 can inhibit disconnection, local thinning, or the like from occurring in the common layer 114 and the common electrode 115 which are provided over the end portion of the side surface of the insulating layer 127, leading to film formation with good coverage. Accordingly, in-plane uniformity of the common layer 114 and the common electrode 115 can be improved, which enables the display quality of the display apparatus to be improved.

In a cross-sectional view of the display apparatus, the top surface of the insulating layer 127 preferably has a convex shape. The convex shape of the top surface of the insulating layer 127 is preferably a shape that expands gradually toward the center. The insulating layer 127 preferably has a shape such that the convex portion at the center portion of the top surface is connected smoothly to the tapered portion of the end portion of the side surface. When the insulating layer 127 has such a shape, the common layer 114 and the common electrode 115 can be formed with good coverage over the whole insulating layer 127.

The insulating layer 127 is formed in a region between two EL layers (e.g., a region between the first layer 113a and the second layer 113b). In that case, at least part of the insulating layer 127 is placed between an end portion of the side surface of one of the EL layers (e.g., the first layer 113a) and an end portion of the side surface of the other of the EL layers (e.g., the second layer 113b).

One end portion of the insulating layer 127 preferably overlaps with the pixel electrode 111a and the other end portion of the insulating layer 127 preferably overlaps with the pixel electrode 111b. With such a structure, the end portion of the insulating layer 127 can be formed over a substantially planar region of the first layer 113a (the second layer 113b). Thus, the tapered shape of the insulating layer 127 is relatively easy to form as described above.

By forming the insulating layer 127 and the like in the above manner, a disconnected portion and a locally thinned portion can be prevented from being formed in the common layer 114 and the common electrode 115 from the substantially planar region of the first layer 113a to the substantially planar region of the second layer 113b. Thus, between the light-emitting devices, a connection defect caused by the disconnected portion and an increase in electric resistance caused by the locally thinned portion can be inhibited from occurring in the common layer 114 and the common electrode 115. Accordingly, the display quality of the display apparatus of one embodiment of the present invention can be improved.

In the display apparatus of this embodiment, the distance between the light-emitting devices can be shortened. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where the distance between two adjacent island-shaped EL layers is less than or equal to 1 μm, preferably less than or equal to 0.5 μm (500 nm), further preferably less than or equal to 100 nm.

Although the structure in which one end portion of the insulating layer 127 overlaps with the pixel electrode 111a and the other end portion of the insulating layer 127 overlaps with the pixel electrode 111b is described above, the present invention is not limited thereto. For example, as illustrated in FIG. 5C, the insulating layer 127 does not necessarily overlap with the pixel electrode 111a and the pixel electrode 111b.

Although FIG. 1B and the like illustrate a structure in which the end portion of the insulating layer 127 is substantially aligned with the end portion of the mask layer 118 and an end portion of the insulating layer 125, the present invention is not limited thereto. For example, the end portion of the insulating layer 127 may be located outward from the end portion of the mask layer 118 and the end portion of the insulating layer 125. In other words, the end portion of the mask layer 118 and the end portion of the insulating layer 125 may be covered with the insulating layer 127. With such a structure, the end portion of the insulating layer 127 and the top surface of the EL layer can be smoothly connected, so that the common layer 114 and the common electrode 115 provided over the insulating layer 127 can be formed with good coverage.

Although all of the thicknesses of the first layer 113a to the third layer 113c are shown as equal in FIG. 1B and the like, the present invention is not limited thereto. The first layer 113a to the third layer 113c may have different thicknesses. The thicknesses may be set in accordance with optical path lengths that intensify light emitted from the first layer 113a to the third layer 113c. This achieves a microcavity structure, so that the color purity of light emitted in each light-emitting devices can be increased.

For example, when the third layer 113c emits light with the longest wavelength and the second layer 113b emits light with the shortest wavelength, the third layer 113c can have the largest thickness and the second layer 113b can have the smallest thickness. Note that without limitation to this, the thicknesses of the EL layers can be adjusted in consideration of the wavelengths of light emitted by the light-emitting elements, the optical characteristics of the layers included in the light-emitting elements, the electrical characteristics of the light-emitting elements, and the like.

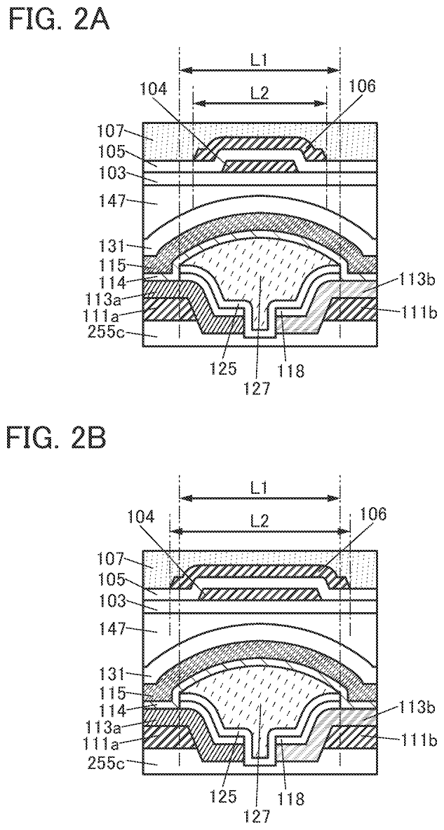

Next, a structure of the touch sensor will be described with reference to FIG. 2A and FIG. 2B. Note that FIG. 2A and FIG. 2B are enlarged views of a region interposed between the first layer 113a and the second layer 113b illustrated in FIG. 1B. Although the description is made with reference to FIG. 2A, FIG. 2B, and the like below, the same applies to a region interposed between the first layer 113a and the third layer 113c, a region interposed between the second layer 113b and the third layer 113c, and the like that are not illustrated in FIG. 2A and FIG. 2B.

The conductive layer 104 is provided over the insulating layer 103. The insulating layer 105 is provided to cover the conductive layer 104 and the insulating layer 103. The conductive layer 106 is provided over the insulating layer 105. The insulating layer 103 is provided over the resin layer 147 which is provided over the protective layer 131. The conductive layer 106 and the insulating layer 105 are bonded to the substrate 102 with the adhesive layer 107.

One or both of the conductive layer 104 and the conductive layer 106 function as electrodes of the touch sensor. Here, an example is shown in which the touch sensor is composed of the conductive layer 104 and the conductive layer 106 that are formed with the insulating layer 105 therebetween.

When the conductive layer 104 and the conductive layer 106 included in the touch sensor are directly formed over the resin layer 147, the thickness of the display apparatus 100 can be made extremely small. Since the conductive layer 104 and the conductive layer 106 are not provided on the substrate 102 side in the display apparatus 100, bonding of the substrate 102 and the substrate 101 does not need high accuracy, which leads to an improvement in the manufacturing yield. The substrate 102 needs at least a light-transmitting property, that is, the degree of freedom in selecting materials is extremely high.

FIG. 1B illustrates a portion where the conductive layer 104 and the conductive layer 106 overlap with each other. For example, the conductive layer 104 and the conductive layer 106 can be used in a portion intersecting with each other. The structure of a connection portion where the conductive layer 104 and the conductive layer 106 are electrically connected to each other is illustrated. In the connection portion, the conductive layer 104 and the conductive layer 106 are electrically connected to each other through an opening provided in the insulating layer 105. The connection portion can be used in a portion where two island-shaped conductive layers 104 are electrically connected to each other by the conductive layer 106, for example.

In FIG. 2A, the conductive layer 104 and the conductive layer 106 are provided other than the light-emitting region of the light-emitting device 130a and the light-emitting region of the light-emitting device 130b. In other words, the conductive layer 104 and the conductive layer 106 overlap with the region interposed between two adjacent light-emitting devices or the region interposed between two adjacent EL layers.

Furthermore, each of the conductive layer 104 and the conductive layer 106 includes a region overlapping with the insulating layer 127. Here, as illustrated in FIG. 2A, a length L2 of the conductive layer 106 in the X1-X2 direction is preferably smaller than a length L1 of the insulating layer 127 in the X1-X2 direction. In other words, the side surface of the conductive layer 104 and the side surface of the conductive layer 106 are preferably located inward from the side surface of the insulating layer 127 (also can be referred to as an end portion of the insulating layer 127) in a cross-sectional view. With such a structure, the conductive layer 104 and the conductive layer 106 can be provided without hindering light emission from the light-emitting device; thus, the touch sensor can be provided in the display apparatus without a reduction in an aperture ratio of the display apparatus 100. Thus, this enables the conductive layer 104 and the conductive layer 106 to be formed using a low-resistance conductive material such as a metal or an alloy, not using a conductive material having a light-transmitting property, whereby the sensitivity of the touch sensor can be increased.

As described above, when the display apparatus of one embodiment of the present invention has the MML structure, the display apparatus can have both a high aperture ratio and a high resolution. Furthermore, when the conductive layer 104 and the conductive layer 106 are provided as described above, the touch sensor can be provided while an aperture ratio is maintained.

Note that although both of the conductive layer 104 and the conductive layer 106 overlap with the region interposed between two adjacent light-emitting devices in FIG. 2A, one embodiment of the present invention is not limited thereto. Either one of the conductive layer 104 and the conductive layer 106 may overlap with the region interposed between two adjacent light-emitting devices or the region interposed between two adjacent EL layers. Either one of the conductive layer 104 and the conductive layer 106 may include a region overlapping with the insulating layer 127.

Although FIG. 2A illustrates the structure in which the length L2 of the conductive layer 106 in the X1-X2 direction is smaller than the length L1 of the insulating layer 127 in the X1-X2 direction, the present invention is not limited thereto. As illustrated in FIG. 2B, a structure in which the length L2 of the conductive layer 106 is larger than the length L1 of the insulating layer 127 in the X1-X2 direction, that is, a structure in which part of the conductive layer 104 and part of the conductive layer 106 do not overlap with the insulating layer 127 can be employed. Note that in order to prevent a reduction in an aperture ratio of the display apparatus, a region where the conductive layer 104 and the conductive layer 106 do not overlap with the insulating layer 127 is preferably small.

A conductive film containing a metal or an alloy can be used for the conductive layer 104 and the conductive layer 106. Examples of materials that can be used for the conductive layer 104 and the conductive layer 106 include metals such as aluminum, titanium, chromium, nickel, copper, yttrium, zirconium, molybdenum, silver, tantalum, and tungsten, and a conductive film containing an alloy containing any of these metals as its main component. A single layer or a stacked-layer structure including a film containing any of these materials can be used. With the use of a conductive film containing a relatively low-resistance metal or alloy as the conductive layer 104 and the conductive layer 106 as described above, the sensitivity of the touch sensor can be increased.

In the case where a conductive material such as a metal or an alloy is used for the conductive layer 104 and the conductive layer 106, reflection of external light due to the conductive layer 104 and the conductive layer 106 might be recognized from the display surface side (the substrate 102 side in FIG. 1B). Thus, a circular polarizing plate (not illustrated) is preferably provided over the substrate 102 to inhibit reflection of external light.

As the insulating layer 105, an inorganic insulating film or an organic insulating film can be used. Examples of insulating materials include a resin such as an acrylic resin and an epoxy resin, and an inorganic insulating material such as silicon oxide, silicon oxynitride, silicon nitride oxide, silicon nitride, and aluminum oxide. The insulating layer 105 may have a single-layer structure or a stacked-layer structure.

The insulating layer 103 preferably contains an inorganic insulating material. Examples of the inorganic insulating material include an oxide and a nitride such as silicon oxide, silicon oxynitride, silicon nitride oxide, silicon nitride, aluminum oxide, aluminum oxynitride, and hafnium oxide.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and precursors of these resins.

As described above, when the protective layer 131, the resin layer 147, and the insulating layer 103 form a stacked-layer structure, even when a defect such as a pinhole exists in the protective layer 131, the defect can be filled with the resin layer 147 with high step coverage, for example. Moreover, by forming the insulating layer 103 over the planar top surface of the resin layer 147, an insulating film with few defects can be formed as the insulating layer 103. When a film containing an inorganic insulating material is used as the insulating layer 103, the conductive layer 104 functions as an etching stopper at the time of processing (etching) the resin layer 147, thereby preventing the resin layer 147 from being etched.

As the adhesive layer 107, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. An adhesive sheet or the like may be used.

A light-blocking layer may be provided on the surface of the adhesive layer 107 side of the substrate 102. A variety of optical members can be arranged on the outer surface of the substrate 102. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be placed as a surface protective layer on the outer surface of the substrate 102. For example, a glass layer or a silica layer (a SiOₓ layer) is preferably provided as the surface protective layer to inhibit the surface contamination and generation of a scratch. The surface protective layer may be formed using DLC (diamond-like carbon), aluminum oxide (AlOₓ), a polyester-based material, a polycarbonate-based material, or the like. For the surface protective layer, a material having high visible-light transmittance is preferably used. The surface protective layer is preferably formed using a material with high hardness.

For the substrate 101 and the substrate 102, glass, quartz, ceramics, sapphire, a resin, a metal, an alloy, a semiconductor, or the like can be used. The substrate on the side from which light from the light-emitting device is extracted is formed using a material which transmits the light. When a material having flexibility is used for the substrate 101 and the substrate 102, the flexibility of the display apparatus can be increased. Furthermore, a polarizing plate may be used as the substrate 101 and the substrate 102.

For each of the substrate 101 and the substrate 102, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a poly amide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 101 and the substrate 102.

Note that in the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the film having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of the display apparatus might be changed, e.g., creases are generated. Thus, for the substrate, a film with a low water absorption rate is preferably used. For example, the water absorption rate of the film is preferably 1% or lower, further preferably 0.1% or lower, further preferably 0.01% or lower.

Next, materials that can be used for the light-emitting device will be described.

A conductive film transmitting visible light is used as the electrode through which light is extracted, which is either the pixel electrode or the common electrode. A conductive film that reflects visible light is preferably used as the electrode through which light is not extracted. In the case where a display apparatus includes a light-emitting device emitting infrared light, a conductive film transmitting visible light and infrared light is used as the electrode through which light is extracted, and a conductive film reflecting visible light and infrared light is preferably used as the electrode through which light is not extracted.

A conductive film transmitting visible light may be used also as the electrode through which light is not extracted. In that case, this electrode is preferably placed between a reflective layer and the EL layer. In other words, light emitted by the EL layer may be reflected by the reflective layer to be extracted from the display apparatus.

As a material that forms the pair of electrodes (the pixel electrode and the common electrode) of the light-emitting device, a metal, an alloy, an electrically conductive compound, a mixture thereof, and the like can be used as appropriate. Specific examples of the material include indium tin oxide (In—Sn oxide, also referred to as ITO), In—Si—Sn oxide (also referred to as ITSO), indium zinc oxide (In—Zn oxide), and In—W—Zn oxide. Other examples include an alloy containing aluminum (aluminum alloy) such as an alloy of aluminum, nickel, and lanthanum (Al—Ni—La), and an alloy containing silver such as an alloy of silver and magnesium and an alloy of silver, palladium, and copper (also referred to as Ag—Pd—Cu or APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting device preferably employs a microcavity structure. Thus, one of the pair of electrodes of the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light at a wavelength longer than or equal to 400 nm and shorter than 750 nm) transmittance higher than or equal to 40% is preferably used in the light-emitting device. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting layer contains a light-emitting material (also referred to as a light-emitting substance). The light-emitting layer can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (guest material). As one or more kinds of organic compounds, one or both of a hole-transport material and an electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of a light-emitting device can be achieved at the same time.

In addition to the light-emitting layer, each of the first layer 113a, the second layer 113b, and the third layer 113c may further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular compound or a high molecular compound can be used for the light-emitting device, and an inorganic compound may also be contained. Each layer included in the light-emitting device can be formed by a method such as an evaporation method (including a vacuum evaporation method), a transfer method, a printing method, an inkjet method, or a coating method.

For example, each of the first layer 113a, the second layer 113b, and the third layer 113c may include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting device does not necessarily include the common layer 114.

Each of the first layer 113a, the second layer 113b, and the third layer 113c preferably includes a light-emitting layer and a carrier-transport layer over the light-emitting layer. Accordingly, the light-emitting layer is inhibited from being exposed on the outermost surface in the manufacturing step of the display apparatus 100, so that damage to the light-emitting layer can be reduced. Thus, the reliability of the light-emitting device can be increased.

The hole-injection layer is a layer injecting holes from an anode to the hole-transport layer, and a layer containing a material with a high hole-injection property. Examples of a material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, an oxide of a metal belonging to any of Group 4 to Group 8 in the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used. As the material with a high hole-injection property, a mixed material in which an oxide of a metal belonging to any of Group 4 to Group 8 in the periodic table (typically, molybdenum oxide) and an organic material are mixed may be used.

The hole-transport layer transports holes injected from the anode by the hole-injection layer, into the light-emitting layer. The hole-transport layer is a layer containing a hole-transport material. As the hole-transport material, a substance having a hole mobility higher than or equal to 1×10⁻⁶ cm²/Vs is preferable. Note that other substances can also be used as long as they have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-transport layer transports electrons injected from the cathode by the electron-injection layer, into the light-emitting layer. The electron-transport layer is a layer containing an electron-transport material. A substance with an electron mobility higher than or equal to 1×10⁻⁶ cm²/Vs is preferable as the electron-transport material. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The electron-injection layer is a layer injecting electrons from the cathode to the electron-transport layer and a layer containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

For the electron-injection layer, an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. In addition, the electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

In the case of manufacturing a tandem light-emitting device, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For the charge-generation layer, for example, a material that can be used for the electron-injection layer, such as lithium, can be suitably used. For the charge-generation layer, for example, a material that can be used for the hole-injection layer can be suitably used. As the charge-generation layer, a layer containing a hole-transport material and an acceptor material (electron-accepting material) can be used. As the charge-generation layer, a layer containing an electron-transport material and a donor material can be used. Forming such a charge-generation layer can inhibit an increase in the driving voltage that would be caused by stacking light-emitting units.

Thin films included in the display apparatus (e.g., insulating films, semiconductor films, and conductive films) can be formed by a sputtering method, a CVD method, a vacuum evaporation method, a PLD method, an ALD method, or the like. Examples of a CVD method include a PECVD method and a thermal CVD method. As an example of the thermal CVD method, a metal organic chemical vapor deposition (MOCVD) method can be given.

Alternatively, thin films included in the display apparatus (e.g., an insulating films, a semiconductor films, and a conductive film) can be formed by a method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

Thin films included in the display apparatus can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are the following two typical methods of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet rays, KrF laser light, ArF laser light, or the like can be used. In addition, light exposure may be performed by liquid immersion exposure technique. As the light used for light exposure, extreme ultraviolet (EUV) light or X-rays may also be used. Instead of the light used for the light exposure, an electron beam can also be used. It is preferable to use EUV light, X-rays, or an electron beam because they can perform extremely minute processing. Note that in the case of performing light exposure by scanning of a beam such as an electron beam, a photomask is not necessarily used.

For etching of thin films, a dry etching method, a wet etching method, a sandblasting method, or the like can be used.

As described above, in the method for manufacturing a display apparatus of this embodiment, the island-shaped EL layers are formed not by using a metal mask having a fine pattern but by processing an EL layer formed over the entire surface. Accordingly, the size of the island-shaped EL layer or even the size of the subpixel can be smaller than that obtained through the formation with a metal mask. Accordingly, a high-resolution display panel or a display panel with a high aperture ratio, each of which has been difficult to achieve, can be obtained.

### [Variation Example 1 of Display Apparatus]

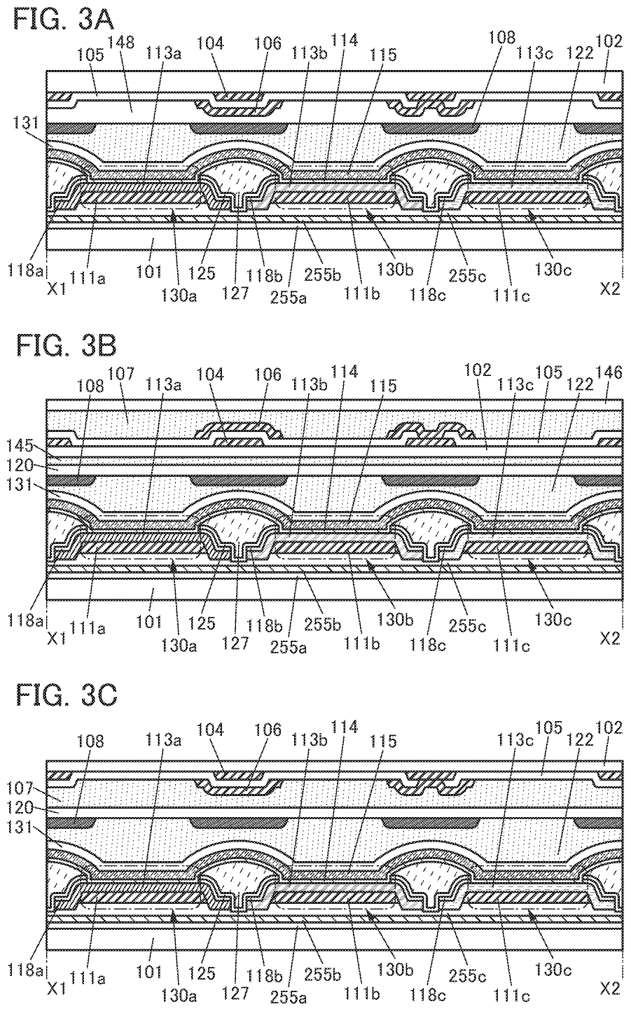

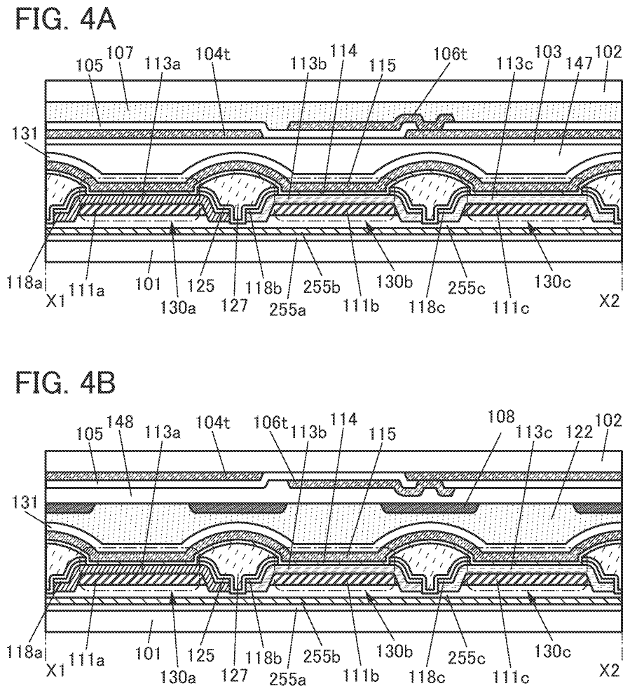

Next, a variation example of the display apparatus 100 in which the structure of the touch sensor is changed are described with reference to FIG. 3A to FIG. 4B. Here, FIG. 3A to FIG. 4B correspond to cross-sectional views along the dashed-dotted line X1-X2 in FIG. 1A. Note that for the components in FIG. 3A to FIG. 4B denoted by the same reference numerals as those in FIG. 1B, the description of FIG. 1B and the like can be referred to.

Although FIG. 1B illustrates a structure in which the touch sensor is provided on the substrate 101 side, the present invention is not limited thereto. For example, as illustrated in FIG. 3A, a structure may be employed in which the display portion is provided over the substrate 101 and the touch sensor is provided on the substrate 102.

In FIG. 3A, the conductive layer 104 is provided over the substrate 102, the insulating layer 105 is provided to cover the conductive layer 104, the conductive layer 106 is provided over the insulating layer 105, a resin layer 148 is provided over the conductive layer 106, and a light-blocking layer 108 is provided over the resin layer 148. Such a substrate 102 and the substrate 101 are bonded to each other with an adhesive layer 122. Thus, the adhesive layer 122 is in contact with the protective layer 131, the resin layer 148, and the light-blocking layer 108. Note that the resin layer 148 can be formed using a material similar to that for the resin layer 147, and the adhesive layer 122 can be formed using a material similar to that for the adhesive layer 107.

The light-blocking layer 108 is provided on the substrate 101 side of the substrate 102. Providing the light-blocking layer 108 can inhibit leakage of light emitted from the light-emitting device 130 into the adjacent subpixel. The light-blocking layer 108 has an opening at least in a position overlapping with the light-emitting device 130. Like the conductive layer 104 and the conductive layer 106, the light-blocking layer 108 preferably includes a region overlapping with the insulating layer 127. In other words, at least part of the light-blocking layer 108 overlaps with a region interposed between two adjacent light-emitting devices or a region interposed between two adjacent EL layers. By providing the light-blocking layer 108 as described above, the light-blocking layer 108 can be provided without a reduction in an aperture ratio.

For the light-blocking layer 108, a material that blocks light emitted from the light-emitting element can be used. The light-blocking layer 108 preferably absorbs visible light. As the light-blocking layer 108, a black matrix can be formed using a metal material or a resin material containing pigment (e.g., carbon black) or dye, for example. The light-blocking layer 108 may have a stacked-layer structure including two or more of a red color filter, a green color filter, and a blue color filter. Note that a structure in which the light-blocking layer 108 is not provided may be employed.

Although FIG. 1B and FIG. 3A each illustrate a structure in which the display portion and the touch sensor are provided between a pair of the substrate 101 and the substrate 102, the present invention is not limited thereto. For example, as illustrated in FIG. 3B, the display portion may be provided between the substrate 101 and the substrate 120, and the touch sensor may be provided between the substrate 102 and the substrate 146.

In the display apparatus illustrated in FIG. 3B, the light-emitting device 130 is provided over the substrate 101, the protective layer 131 is provided over the light-emitting device 130, the light-blocking layer 108 is provided over the substrate 120, and the substrate 101 and the substrate 120 are bonded to each other with the adhesive layer 122. Here, the adhesive layer 122 is in contact with the protective layer 131, the substrate 120, and the light-blocking layer 108. The conductive layer 104 is provided over the substrate 102, the insulating layer 105 is provided to cover the conductive layer 104, the conductive layer 106 is provided over the insulating layer 105, and the substrate 102 and the substrate 146 are bonded to each other with the adhesive layer 107. The substrate 120 and the substrate 102 are bonded to each other with an adhesive layer 145. Note that the substrate 120 and the substrate 146 can be formed using a material similar to that for the substrate 102, and the adhesive layer 145 can be formed using a material similar to that for the adhesive layer 107.

As illustrated in FIG. 3C, a structure may be employed in which the display portion is provided between the substrate 101 and the substrate 120, the touch sensor is provided on the substrate 102, and the substrate 120 and the substrate 102 are bonded to each other with the adhesive layer 107. In this case, the adhesive layer 107 is in contact with the substrate 120, the insulating layer 105, and the conductive layer 106. With such a structure, the number of necessary substrates can be reduced by one as compared with the display apparatus illustrated in FIG. 3B; thus, the display apparatus can be thinner than the display apparatus illustrated in FIG. 3B.

An example of the case where a light-transmitting conductive film is used as the electrode of the touch sensor is described with reference to FIG. 4A and FIG. 4B.

The display apparatus illustrated in FIG. 4A is different from the display apparatus illustrated in FIG. 1B in that a light-transmitting conductive film is used as the electrode of the touch sensor.

In the display apparatus illustrated in FIG. 4A, in the structure of the display apparatus illustrated in FIG. 1B, a conductive layer 104t is provided instead of the conductive layer 104 and a conductive layer 106t is provided instead of the conductive layer 106. Note that in the display apparatus illustrated in FIG. 4A, the conductive layer 104t and the conductive layer 106t are each provided also in a region overlapping with the light-emitting device 130. Note that in FIG. 4A, an opening is provided in part of the insulating layer 105, and a connection portion where the conductive layer 104t and the conductive layer 106t are electrically connected to each other through the opening is also illustrated.

The conductive layer 104t and the conductive layer 106t contain a conductive material that has a light-transmitting property with respect to visible light. For the conductive layer 104t and the conductive layer 106t, a material having a light-transmitting property with respect to at least light emitted from the light-emitting device 130 can be used.

The conductive layer 104t and the conductive layer 106t have a light-transmitting property, and thus can be placed to overlap with the light-emitting device 130. Accordingly, the layout flexibility of the conductive layer 104t and the conductive layer 106t serving as electrodes of the touch sensor can be increased.

The display apparatus using the light-transmitting conductive film as the electrode of the touch sensor is not limited to the display apparatus illustrated in FIG. 4A. For example, as illustrated in FIG. 4B, the conductive layer 104t and the conductive layer 106t having a light-transmitting property may be used as the electrodes of the touch sensor in the display apparatus illustrated in FIG. 3A.

Note that in the display apparatus 100 illustrated in FIG. 4A and FIG. 4B, either one of the conductive layer 104t and the conductive layer 106t may be replaced with a conductive layer containing a metal or an alloy. In that case, the light-transmitting conductive layer is placed to overlap with the light-emitting device 130, and the conductive layer containing a metal or an alloy can be placed at a position not overlapping with the light-emitting device 130. When a low-resistance conductive layer is used as part of the conductive layer included in the touch sensor, the electric resistance can be reduced and the sensitivity can be improved.

### [Variation Example 2 of Display Apparatus]

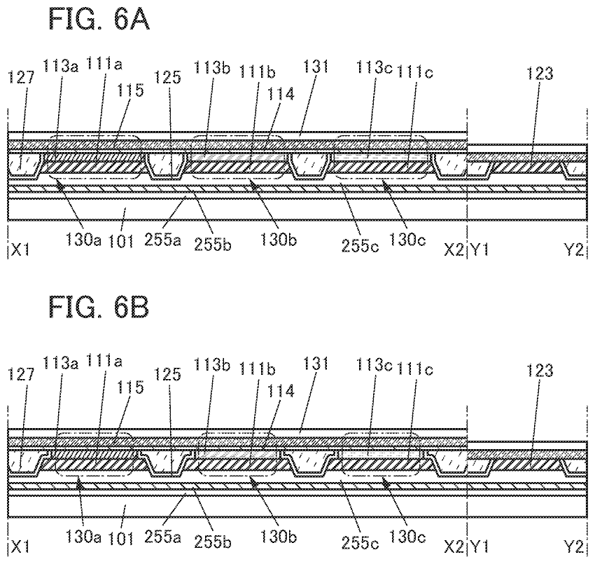

Next, variation examples of the display apparatus 100 in which the structures of the display portion and the connection portion are changed are described with reference to FIG. 6A to FIG. 8C. Here, FIG. 6A to FIG. 8C correspond to cross-sectional views along the dashed-dotted line X1-X2 and cross-sectional views along the dashed-dotted line Y1-Y2 in FIG. 1A. In FIG. 6A to FIG. 8C, the structure above the protective layer 131 is not illustrated. The touch sensor having any of the structures illustrated in FIG. 1B, FIG. 3A to FIG. 4B, and the like can be provided as appropriate over the protective layer 131.

FIG. 6A illustrates an example where the end portion of the top surface of the pixel electrode 111a and the end portion of the first layer 113a are aligned or substantially aligned with each other. FIG. 6A illustrates an example where the end portion of the first layer 113a is located inward from the end portion of the bottom surface of the pixel electrode 111a. FIG. 6B illustrates an example where the end portion of the first layer 113a is located inward from the end portion of the top surface of the pixel electrode 111a. In FIG. 6A and FIG. 6B, the end portion of the first layer 113a is located over the pixel electrode 111a.

As illustrated in FIG. 6A and FIG. 6B, when the end portion of the first layer 113a is located over the pixel electrode 111a, a reduction in the thickness of the first layer 113a in or in the vicinity of the end portion of the pixel electrode 111a can be inhibited to make the thickness of the first layer 113a uniform.

In the case where end portions are aligned or substantially aligned with each other and in the case where top surface shapes are the same or substantially the same, it can be said that outlines of stacked layers at least partly overlap with each other in a top view. For example, the case of processing the upper layer and the lower layer with the use of the same mask pattern or mask patterns that are partly the same is included. However, in some cases, the outlines do not overlap with each other and the upper layer is located inward from the lower layer or the upper layer is located outward from the lower layer; such a case is also represented by the expression “end portions are substantially aligned with each other” or “top surface shapes are substantially the same”.

The end portion of the first layer 113a may have both a portion located outward from the end portion of the pixel electrode 111a and a portion located inward from the end portion of the pixel electrode 111a.

As illustrated in FIG. 6A and FIG. 6B, the side surfaces of the pixel electrodes 111a, 111b, and 111c, the first layer 113a, the second layer 113b, and the third layer 113c are each covered with the insulating layer 125 and the insulating layer 127. Thus, the common layer 114 (or the common electrode 115) can be inhibited from being in contact with the side surfaces of the pixel electrodes 111a, 111b, and 111c, the first layer 113a, the second layer 113b, and the third layer 113c, whereby a short circuit of the light-emitting device can be inhibited. Thus, the reliability of the light-emitting device can be increased.

Also in the display apparatus illustrated in FIG. 6A and FIG. 6B, as in the above-described structure, at least part of the conductive layer 104 and part of the conductive layer 106 preferably overlap with the region interposed between two adjacent light-emitting devices or the region interposed between two adjacent EL layers. Furthermore, at least part of the conductive layer 104 and part of the conductive layer 106 preferably include the region overlapping with the insulating layer 127. With such a structure, the touch sensor can be provided while a high aperture ratio of the display apparatus is maintained.

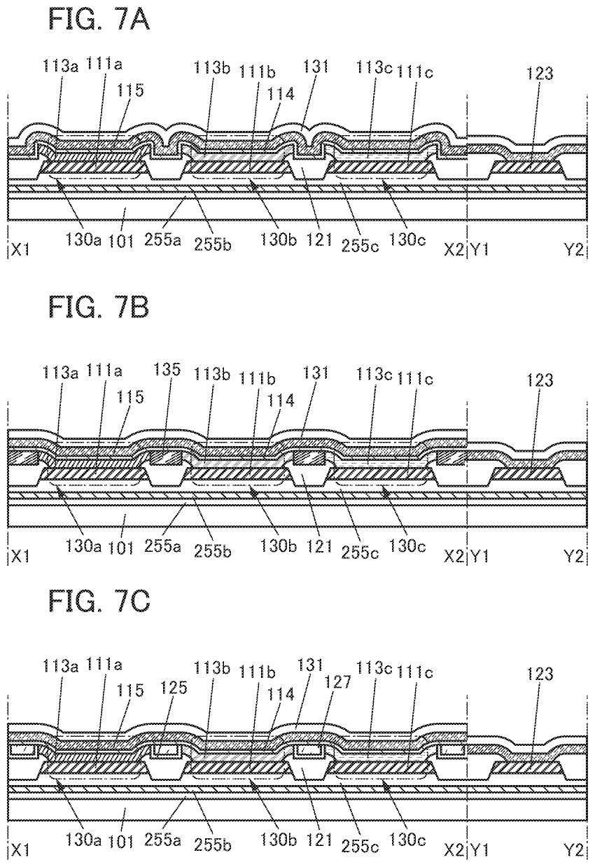

As illustrated in FIG. 7A to FIG. 7C, the insulating layer 121 covering the end portions of the top surfaces of the pixel electrode 111a, 111b, and 111c may be provided. The first layer 113a, the second layer 113b, and the third layer 113c can each have a portion that is over and in contact with the pixel electrode and a portion that is over and in contact with the insulating layer 121. The insulating layer 121 can have a single-layer structure or a stacked-layer structure using one or both of an inorganic insulating film and an organic insulating film.

Examples of an organic insulating material that can be used for the insulating layer 121 include an acrylic resin, an epoxy resin, a polyimide resin, a polyamide resin, a polyimide-amide resin, a polysiloxane resin, a benzocyclobutene-based resin, and a phenol resin. As an inorganic insulating film that can be used as the insulating layer 121, an inorganic insulating film that can be used as the protective layer 131 can be used.

When an inorganic insulating film is used as the insulating layer 121, impurities are less likely to enter the light-emitting devices as compared with the case where an organic insulating film is used; thus, the reliability of the light-emitting devices can be improved. Furthermore, the insulating layer 121 can be thinner, so that high resolution can be easily achieved. Meanwhile, when an organic insulating film is used as the insulating layer 121, better step coverage than the case of using an inorganic insulating film can be obtained; thus, an influence of the shape of the pixel electrodes can be small. Thus, a short circuit in the light-emitting devices can be prevented. Specifically, when an organic insulating film is used as the insulating layer 121, the insulating layer 121 can be processed into a tapered shape or the like.

Note that the insulating layer 121 is not necessarily provided. An aperture ratio of the subpixel can be sometimes increased without providing the insulating layer 121. Alternatively, the distance between subpixels can be shortened and the resolution or the definition of the display apparatus can be sometimes increased.

Note that FIG. 7A illustrates an example in which the common layer 114 falls in a region between the first layer 113a and the second layer 113b, a region between the second layer 113b and the third layer 113c, and the like over the insulating layer 121. As illustrated in FIG. 7B, a gap 135 may be formed in the region.

The gap 135 contains, for example, one or more selected from air, nitrogen, oxygen, carbon dioxide, and Group 18 elements (typified by helium, neon, argon, xenon, krypton, and the like). Alternatively, a resin or the like may fill the gap 135.

As illustrated in FIG. 7C, the insulating layer 125 may be provided to cover the top surface of the insulating layer 121 and the side surfaces of the first layer 113a, the second layer 113b, and the third layer 113c, and the insulating layer 127 may be provided over the insulating layer 125.

Also in the display apparatus illustrated in FIG. 7A to FIG. 7C, as in the above-described structure, at least part of the conductive layer 104 and part of the conductive layer 106 preferably overlap with the region interposed between two adjacent light-emitting devices or the region interposed between two adjacent EL layers. Furthermore, at least part of the conductive layer 104 and part of the conductive layer 106 preferably include a region overlapping with the insulating layer 121. With such a structure, the touch sensor can be provided while a high aperture ratio of the display apparatus is maintained.

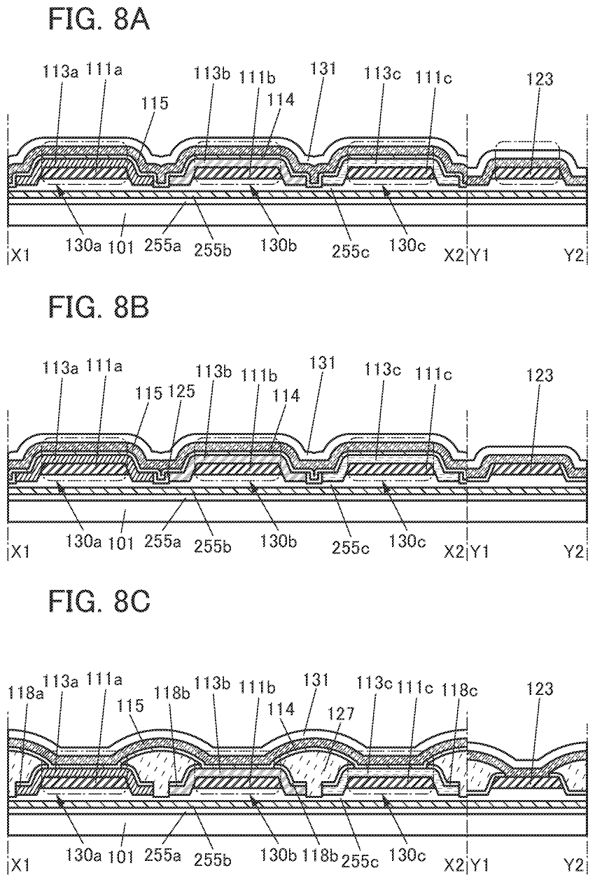

Note that as illustrated in FIG. 8A, the display apparatus does not necessarily include the insulating layer 125 and the insulating layer 127. FIG. 8A illustrates an example in which the common layer 114 is provided in contact with the top surface of the insulating layer 255c, the side surfaces and the top surfaces of the first layer 113a, the second layer 113b, and the third layer 113c. As illustrated in FIG. 7B, the gap 135 may be provided in a region between the first layer 113a and the second layer 113b, a region between the second layer 113b and the third layer 113c, and the like.

Note that one of the insulating layer 125 and the insulating layer 127 is not necessarily provided. When the insulating layer 125 having a single-layer structure using an inorganic material is formed, for example, the insulating layer 125 can be used as a protective insulating layer for the EL layer. This leads to higher reliability of the display apparatus. For another example, when the insulating layer 127 having a single-layer structure using an organic material is formed, the insulating layer 127 can fill a gap between the adjacent island-shaped EL layers for planarization. In this way, the coverage with the common electrode 115 (the upper electrode) formed over the island-shaped EL layer and the insulating layer 127 can be increased.

FIG. 8B illustrates an example where the insulating layer 127 is not provided. Note that although FIG. 8B illustrates an example in which the common layer 114 is provided in the concave portion of the insulating layer 125, spaces may be formed in the regions.

The insulating layer 125 includes a region in contact with the side surface of the island-shaped EL layer and functions as a protective insulating layer of the EL layer. Providing the insulating layer 125 can inhibit entry of impurities (e.g., oxygen and moisture) into the inside of the island-shaped EL layer through its side surface, resulting in a highly reliable display apparatus.

FIG. 8C illustrates an example where the insulating layer 125 is not provided. In the case where the insulating layer 125 is not provided, the insulating layer 127 can be in contact with the side surface of the island-shaped EL layer. The insulating layer 127 can be provided to fill gaps between the island-shaped EL layers of the light-emitting devices.

In this case, an organic material that causes less damage to the EL layer is preferably used for the insulating layer 127. For example, it is preferable to use, for the insulating layer 127, an organic material such as polyvinyl alcohol (PVA), polyvinyl butyral, polyvinyl pyrrolidone, polyethylene glycol, polyglycerin, pullulan, water-soluble cellulose, or alcohol-soluble polyamide resin.

Also in the display apparatus illustrated in FIG. 8A to FIG. 8C, as in the above-described structure, at least part of the conductive layer 104 and part of the conductive layer 106 preferably overlap with the region interposed between two adjacent light-emitting devices or the region interposed between two adjacent EL layers. With such a structure, the touch sensor can be provided while a high aperture ratio of the display apparatus is maintained.

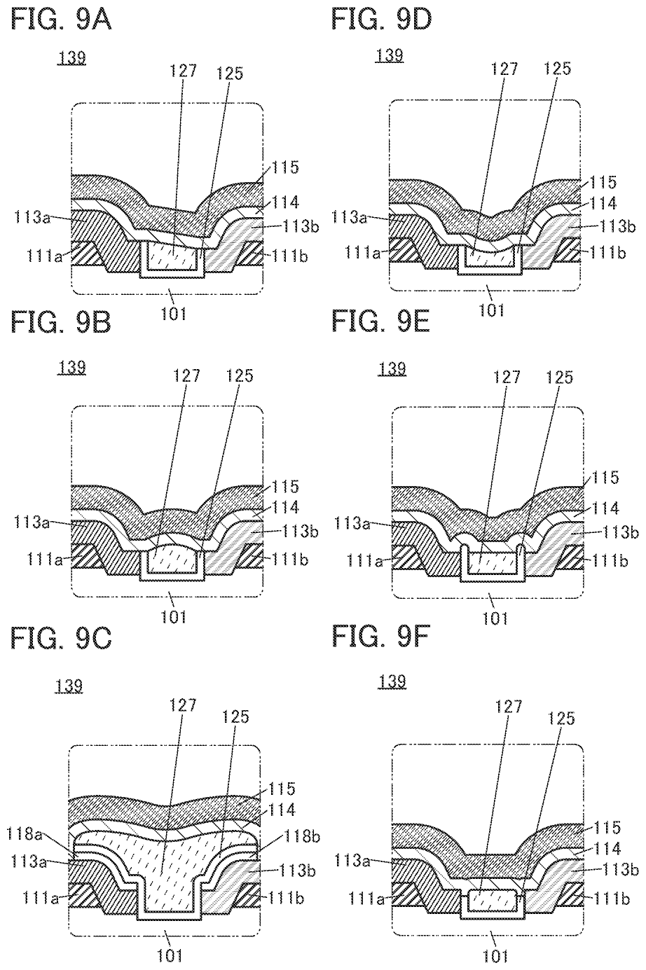

FIG. 9A to FIG. 9F illustrate cross-sectional structures of a region 139 including the insulating layer 127 and its periphery.

FIG. 9A illustrates an example where the first layer 113a and the second layer 113b have different thicknesses. The level of the top surface of the insulating layer 125 is equal to or substantially equal to the level of the top surface of the first layer 113a on the first layer 113a side, and is equal to or substantially equal to the level of the top surface of the second layer 113b on the second layer 113b side. The top surface of the insulating layer 127 has a gentle slope such that the side closer to the first layer 113a is higher and the side closer to the second layer 113b is lower. In this manner, the levels of the insulating layer 125 and the insulating layer 127 are preferably equal to the level of the top surface of the adjacent EL layers. Alternatively, the top surface levels of the insulators may be equal to the top surface level of any adjacent EL layer so that their top surfaces have a planar portion.

In FIG. 9B, the top surface of the insulating layer 127 includes a region that is at a higher level than the top surface of the first layer 113a and the top surface of the second layer 113b. As illustrated in FIG. 9B, the top surface of the insulating layer 127 can have, in a cross-sectional view, a shape in which the center and its vicinity are bulged, i.e., a shape including a convex surface.

In the cross-sectional view of FIG. 9C, the top surface of the insulating layer 127 has a shape that gradually expands toward the center, i.e., has a convex surface, and has a shape that is recessed in the center and its vicinity, i.e., has a concave surface. The insulating layer 127 includes a region that is at a higher level than the top surface of the first layer 113a and the top surface of the second layer 113b. The region 139 of the display apparatus includes a region where the first layer 113a, the mask layer 118a, the insulating layer 125, and the insulating layer 127 are stacked in this order. The region 139 of the display apparatus includes a region where the second layer 113b, the mask layer 118b, the insulating layer 125, and the insulating layer 127 are stacked in this order.

In FIG. 9D, the top surface of the insulating layer 127 includes a region that is at a lower level than the top surface of the first layer 113a and the top surface of the second layer 113b. In the cross-sectional view, the top surface of the insulating layer 127 has a recessed portion in the center and its vicinity, i.e., has a concave curved surface.

In FIG. 9E, the top surface of the insulating layer 125 includes a region that is at a higher level than the top surface of the first layer 113a and the top surface of the second layer 113b. That is, the insulating layer 125 protrudes from the formation surface of the common layer 114 and forms a convex portion.

In formation of the insulating layer 125, for example, when the insulating layer 125 is formed to be level or substantially level with the mask layer, a shape such that the insulating layer 125 protrudes is sometimes formed as illustrated in FIG. 9E.

In FIG. 9F, the top surface of the insulating layer 125 includes a region that is at a lower level than the top surface of the first layer 113a and the top surface of the second layer 113b. That is, the insulating layer 125 forms a concave portion on the formation surface of the common layer 114.

As described above, the insulating layer 125 and the insulating layer 127 can have a variety of shapes.

In the display apparatus of one embodiment of the present invention, at least part of the electrode of the touch sensor overlaps with the region interposed between two adjacent light-emitting devices or the region interposed between two adjacent EL layers. Furthermore, at least part of the electrode of the touch sensor preferably includes the region overlapping with the organic resin film provided between two adjacent EL layers. With such a structure, the touch sensor can be provided while a high aperture ratio of the display apparatus is maintained. Thus, a display apparatus having both a high aperture ratio and a high resolution can be provided.

This embodiment can be combined with the other embodiments as appropriate.

### Embodiment 2

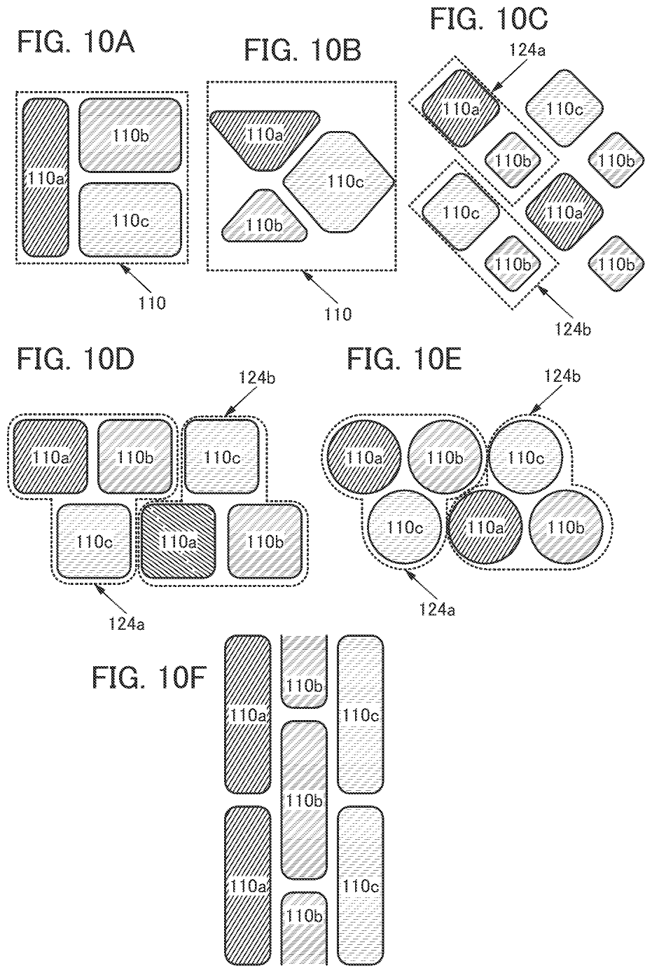

In this embodiment, a display apparatus of one embodiment of the present invention is described with reference to FIG. 10 to FIG. 12.

In this embodiment, pixel layouts different from that in FIG. 1A are mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

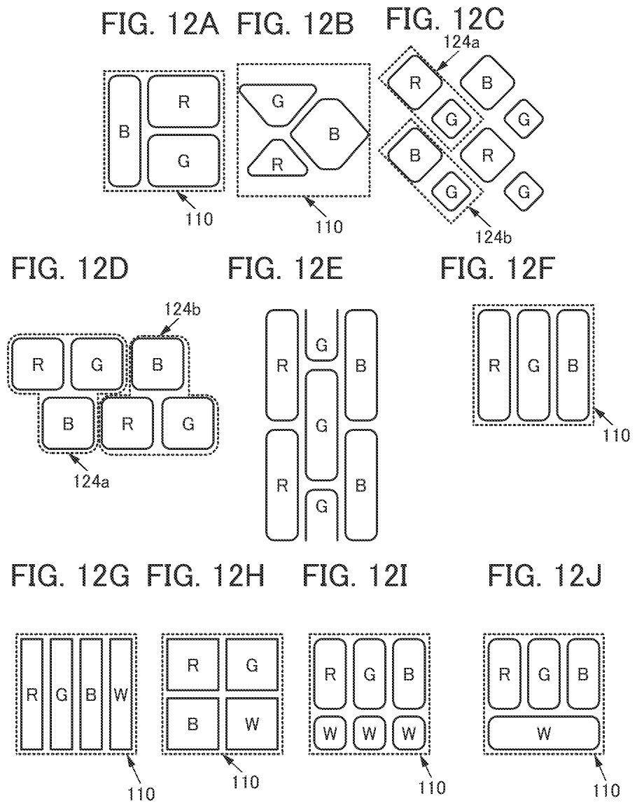

The pixel 110 illustrated in FIG. 10A employs S-stripe arrangement. The pixel 110 illustrated in FIG. 10A is composed of three subpixels 110a, 110b, and 110c. For example, as illustrated in FIG. 12A, the subpixel 110a may be a blue subpixel B, the subpixel 110b may be a red subpixel R, and the subpixel 110c may be a green subpixel G.

The pixel 110 illustrated in FIG. 10B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 12B, the subpixel 110a may be the green subpixel G, the subpixel 110b may be the red subpixel R, and the subpixel 110c may be the blue subpixel B.

Pixels 124a and 124b illustrated in FIG. 10C employ PenTile arrangement. FIG. 10C illustrates an example in which the pixels 124a each including the subpixel 110a and the subpixel 110b and the pixels 124b each including the subpixel 110b and the subpixel 110c are alternately arranged. For example, as illustrated in FIG. 12C, the subpixel 110a may be the red subpixel R, the subpixel 110b may be the green subpixel G, and the subpixel 110c may be the blue subpixel B.

The pixels 124a and 124b illustrated in FIG. 10D and FIG. 10E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 12D, the subpixel 110a may be the red subpixel R, the subpixel 110b may be the green subpixel G, and the subpixel 110c may be the blue subpixel B.

FIG. 10D illustrates an example in which the top surface of each subpixel has a rough tetragonal shape with rounded corners, and FIG. 10E illustrates an example in which the top surface of each subpixel is circular.

FIG. 10F illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 12E, the subpixel 110a may be the red subpixel R, the subpixel 110b may be the green subpixel G, and the subpixel 110c may be the blue subpixel B.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel can have a polygonal shape with rounded corners, an elliptical shape, a circular shape, or the like.

Furthermore, in the method for manufacturing the display apparatus of one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

Also in the pixel 110 illustrated in FIG. TA, which employs stripe arrangement, for example, the subpixel 110a can be the red subpixel R, the subpixel 110b can be the green subpixel G, and the subpixel 110c can be the blue subpixel B as illustrated in FIG. 12F.

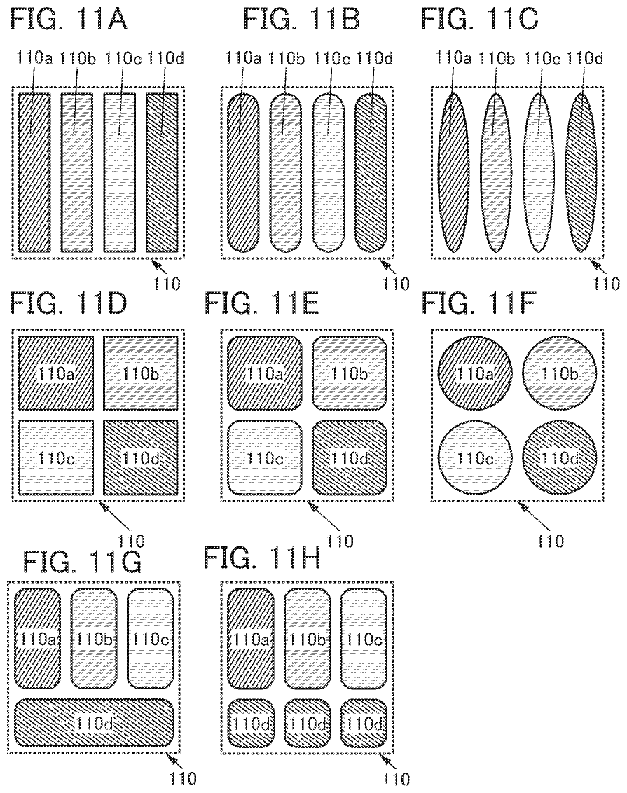

As illustrated in FIG. 11A to FIG. 11H, the pixel can include four types of subpixels.

The pixels 110 illustrated in FIG. 11A to FIG. 11C employ stripe arrangement.

FIG. 11A illustrates an example in which each subpixel has a rectangular top surface, FIG. 11B illustrates an example in which each subpixel has a top surface shape formed by combining two half circles and a rectangle, and FIG. 11C illustrates an example in which each subpixel has an elliptical top surface.

The pixels 110 illustrated in FIG. 11D to FIG. 11F employ matrix arrangement.

FIG. 11D illustrates an example in which each subpixel has a square top surface, FIG. 11E illustrates an example in which each subpixel has a substantially square top surface with rounded corners, and FIG. 11F illustrates an example in which each subpixel has a circular top surface.

FIG. 11G and FIG. 11H each illustrate an example in which one pixel 110 is composed of two rows and three columns.

The pixel 110 illustrated in FIG. 11G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 11H includes three subpixels (the subpixels 110a, 110b, and 110c) in the upper row (first row) and three the subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 11H enables dust and the like that would be produced in the manufacturing process to be removed efficiently. Thus, a display apparatus with high display quality can be provided.

The pixels 110 illustrated in FIG. 11A to FIG. 11H are each composed of the four subpixels 110a, 110b, 110c, and 110d. The subpixels 110a, 110b, 110c, and 110d include light-emitting devices that emit light of different colors. The subpixels 110a, 110b, 110c, and 110d can be subpixels of four colors of R, G, B, and white (W), subpixels of four colors of R, G, B, and Y, subpixels of R, G, B, and infrared light (IR), or the like. For example, the subpixels 110a, 110b, 110c, and 110d can be subpixels of red, green, blue, and white, respectively, as illustrated in FIG. 12G to FIG. 12J. Note that the number of kinds of subpixels is not limited to four and may be five or more.

As described above, the pixel composed of the subpixels each including the light-emitting device can employ any of a variety of layouts in the display panel of one embodiment of the present invention.

This embodiment can be combined with the other embodiments as appropriate.

### Embodiment 3

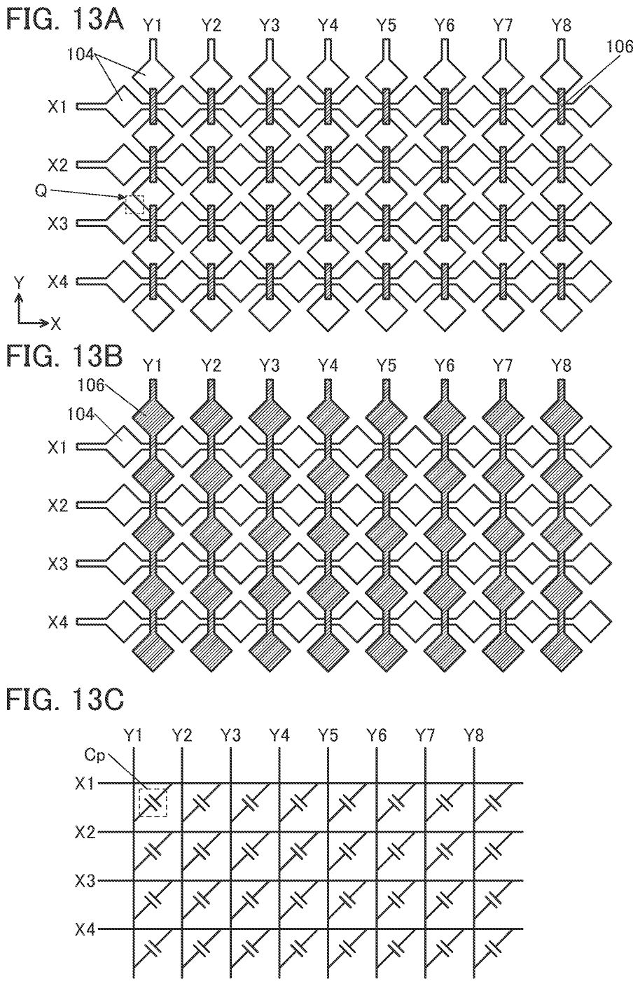

In this embodiment, a structure example of the touch sensor used in the display apparatus of one embodiment of the present invention will be described with reference to FIG. 13 to FIG. 17. Here, a capacitive touch sensor is described.

Typical examples of the capacitive touch sensor include a self-capacitive type and a mutual capacitive type.

In a self-capacitive type, an electrode to which a capacitor is connected forms a segment, and a structure in which a plurality of the segments are arranged in a matrix is employed. The self-capacitive type is a method for obtaining positional data by detecting an increase in the capacitance of the electrode when an object to be sensed such as a finger approaches the electrode.

In a mutual capacitive type, a structure where a plurality of first wirings and a plurality of second wirings are arranged in directions intersecting with each other is employed. The mutual capacitive type is a method for obtaining positional data by detecting a change in capacitance formed at an intersection portion of the first wiring and the second wiring when an object to be sensed approaches.

A structure that can be employed for a mutual capacitive type is described below.

### [Structure Example of Touch Sensor]

FIG. 13A is a schematic top view illustrating an example of a conductive layer included in the touch sensor. The touch sensor illustrated in FIG. 13A includes the conductive layer 104 and the conductive layer 106.

The touch sensor includes a plurality of wirings extending in the X direction and arranged in the Y direction (a wiring X1 to a wiring X4) and a plurality of wirings extending in the Y direction and arranged in the X direction (a wiring Y1 to a wiring Y8). Hereinafter, an expression “wiring Xn” is used for describing the matter common to the wiring X1 to the wiring X4, and an expression “wiring Yin” is used for describing the matter common to the wiring Y1 to the wiring Y8.

A wiring Xn is formed using the conductive layer 104. The wiring Xn has a shape in which portions elongated in the X direction and rhombic portions are alternately connected to each other.

The wiring Ym includes the conductive layer 104 and the conductive layer 106. The wiring Ym is composed of a plurality of rhombic conductive layers 104 and the conductive layers 106 elongated in the Y direction, connecting the conductive layers 104.

The wiring Xn and the wiring Ym intersect with each other by a narrow portion composed of the conductive layer 104 of the wiring Xn and a narrow portion composed of the conductive layer 106 of the wiring Ym.

Note that as illustrated in FIG. 13B, the wiring Xn may be formed using the conductive layer 104, and the wiring Ym may be formed using the conductive layer 106.

Although FIG. 13A and FIG. 13B illustrate examples in which four wirings Xn and eight wirings Ym are included, the number of wirings is not limited thereto and can be set as appropriate depending on the size of a display portion of a display apparatus or required wiring density of a touch sensor.

FIG. 13C is a circuit diagram illustrating the structure of the touch sensor. Since the capacitive coupling is generated between the wiring Xn and the wiring Ym, capacitance Cp is formed therebetween. The capacitance Cp is sometimes referred to as a mutual capacitance between the wiring Xn and the wiring Ym. Here, a circuit supplied with a pulse potential is connected to the wiring Xn, and a circuit for obtaining the potential of the wiring Ym, such as an A/D converter circuit or a sense amplifier, is connected to the wiring Ym.

Since the capacitive coupling is formed between the wiring Xn and the wiring Ym, when a pulse potential is supplied to the wiring Xn, a pulse potential is generated in the wiring Ym. The amplitude of the pulse potential generated in the wiring Ym is proportional to the intensity of the capacitive coupling between the wiring Xn and the wiring Ym (i.e., the capacitance of the Cp). When an object to be sensed such as a finger approaches the vicinity of the intersection portion of the wiring Xn and the wiring Ym, capacitance is formed between the wiring Xn and the object to be sensed and between the wiring Ym and the object to be sensed; as a result, the intensity of the capacitive coupling between the wiring Xn and the wiring Ym becomes relatively small. Thus, when a pulse potential is supplied to the wiring Xn, the amplitude of a pulse potential generated in the wiring Ym is reduced.

When a pulse potential is supplied to the wiring X1, pulse potentials generated in the wiring Y1 to the wiring Y8 are obtained. Similarly, pulse potentials are supplied to the wiring X2, the wiring X3, and the wiring X4 in this order, and pulse potentials generated in the wiring Y1 to the wiring Y8 at this time are obtained. Accordingly, positional data of an object to be sensed can be obtained.

### [Structure Example 1 of Electrode Shape]

More specific examples of top surface shapes of electrodes of the wiring Xn and the wiring Ym are described below.

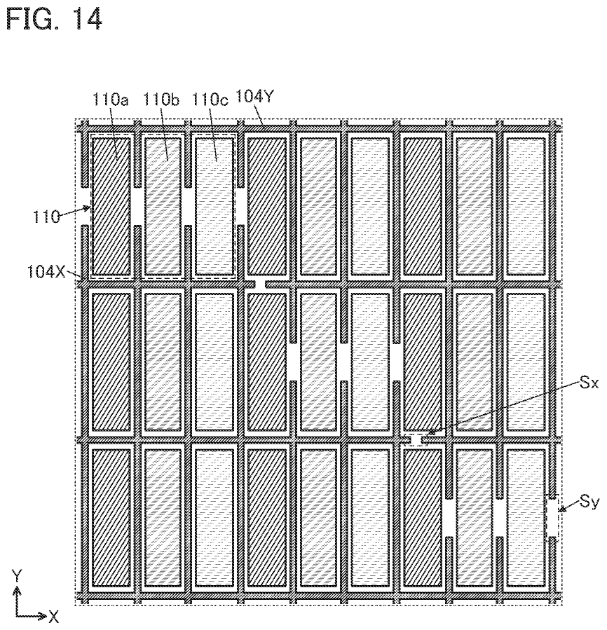

FIG. 14 illustrates an enlarged view of a region Q in FIG. 13A. The region Q is a region including the rhombic portion of the wiring Xn, the rhombic portion of the wiring Ym, and a boundary therebetween.

FIG. 14 illustrates top surface shapes of a conductive layer 104X that forms the wiring Xn and a conductive layer 104Y that forms the wiring Ym. The conductive layer 104X and the conductive layer 104Y each have the lattice-shaped top surface. In other words, the conductive layer 104X and the conductive layer 104Y each have a top surface shape having a plurality of openings. The conductive layer 104X and the conductive layer 104Y may be formed over different planes, but it is particularly preferable that the conductive layer 104X and the conductive layer 104Y be located on the same plane and formed by processing the same conductive film.

FIG. 14 also illustrates a pixel 110. The pixel 110 includes a subpixel 110a, a subpixel 110b, and a subpixel 110c. For example, the subpixel 110a may be a blue subpixel B, the subpixel 110b may be a red subpixel R, and the subpixel 110c may be a green subpixel G.

The conductive layer 104X and the conductive layer 104Y are provided between adjacent subpixels in a plan view. In other words, each of the subpixel 110a, the subpixel 110b, and the subpixel 110c is provided at a position overlapping with an opening included in the conductive layer 104X or the conductive layer 104Y. Here, an example in which one subpixel is provided at a position overlapping with one opening included in the conductive layer 104X or the conductive layer 104Y in a plan view is illustrated. Note that without limitation to this structure, a structure in which a plurality of subpixels are provided at a position overlapping with one opening may be employed.

The lattice-shaped top surface of each of the conductive layer 104X and the conductive layer 104Y is formed by a portion extending in the X direction, a portion extending in the Y direction, and their intersection portions. The conductive layer 104X and the conductive layer 104Y are separated from each other by notches Sx provided in the portion extending in the X direction of the lattice-shaped conductive layer and notches Sy provided in the portion extending in the Y direction of the lattice-shaped conductive layer. With such a structure, a distance between the conductive layer 104X and the conductive layer 104Y can be made small, whereby the capacitance value therebetween can be increased.

Although a notch may be provided at the intersection portion of the lattice, it is preferable that the notches Sx and the notches Sy be respectively placed in the portion extending in the X direction and the portion extending in the Y direction of the lattice as illustrated in FIG. 14, whereby the patterns of the conductive layer 104X and the conductive layer 104Y can be less likely to be recognized when seen from the display surface side.

As illustrated in FIG. 14, around the subpixel 110a, the subpixel 110b, and the subpixel 110c, a structure where part of the conductive layer 104X or part of the conductive layer 104Y is always provided adjacent to each other is employed. With such a structure, the patterns of the conductive layer 104X and the conductive layer 104Y can be less likely to be recognized when seen from the display surface side.

In FIG. 14, each of the conductive layer 104X and the conductive layer 104Y has the lattice-shaped top surface having vertically long openings. The subpixel 110a, the subpixel 110b, and the subpixel 110c are each placed to overlap with one opening. In the pixel 110 illustrated in FIG. 14, the subpixel 110a, the subpixel 110b, and the subpixel 110c are arranged in the Y direction, as in FIG. TA. Note that in the pixel 110, the positions of the subpixel 110a, the subpixel 110b, and the subpixel 110c are not limited thereto, and arbitrarily-chosen two positions can be interchanged.

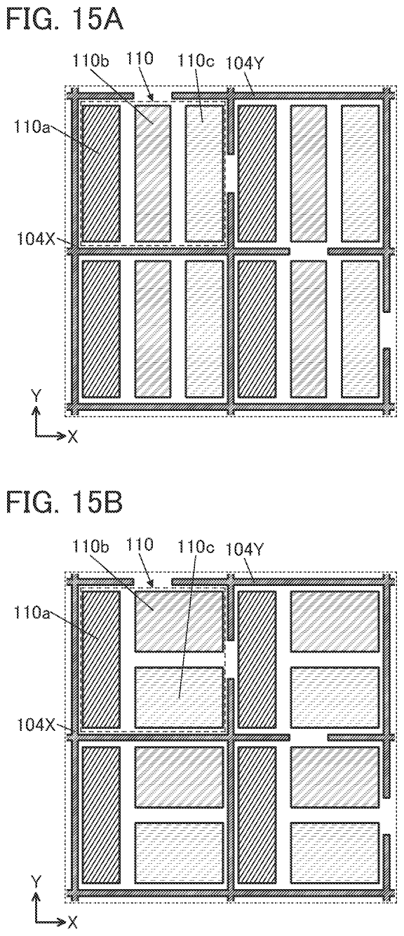

Note that the positions of the pixel and the touch sensor of the present invention are not limited to the positions illustrated in FIG. 14. For example, as illustrated in FIG. 15A, the subpixel 110a, the subpixel 110b, and the subpixel 110c may be collectively arranged in one opening included in the conductive layer 104X and the conductive layer 104Y. That is, a structure may be possible in which not one subpixel, rather, a pixel including a plurality of subpixels are arranged in one opening included in the conductive layer 104X and the conductive layer 104Y.

In FIG. 15A, although the pixel 110 has stripe arrangement similar to that in FIG. TA, the arrangement is not limited thereto. For example, as illustrated in FIG. 15B, the pixel 110 may have S-stripe arrangement as illustrated in FIG. 10A. For example, the subpixel 110a may be the blue subpixel B, the subpixel 110b may be the red subpixel R, and the subpixel 110c may be the green subpixel G.

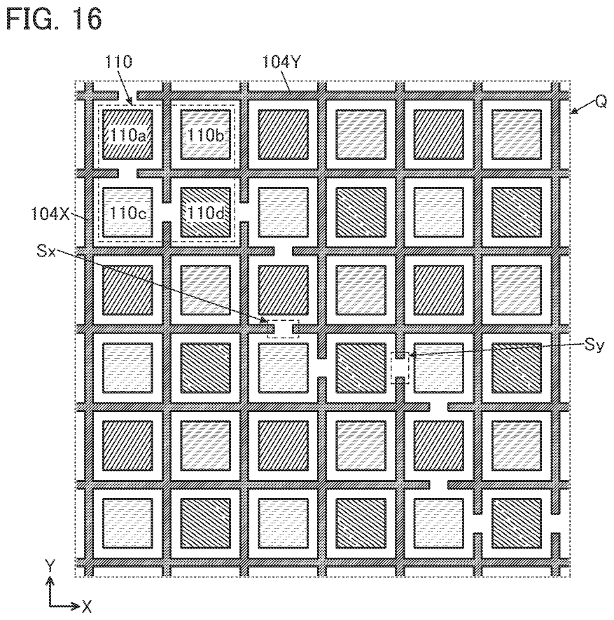

Alternatively, the pixel 110 may include four or more subpixels. As illustrated in FIG. 16, the pixel 110 may include the subpixel 110a, the subpixel 110b, the subpixel 110c, and a subpixel 110d. In the display apparatus illustrated in FIG. 16, the pixels 110 are arranged in a matrix like FIG. 11D. The subpixel 110a and the subpixel 110b are alternately arranged in the X direction. The subpixel 110c and the subpixel 110d are alternately arranged in the X direction.

The subpixel 110a and the subpixel 110c are alternately arranged in the Y direction. The subpixel 110b and the subpixel 110d are alternately arranged in the Y direction. For example, the subpixel 110a may be the red subpixel R, the subpixel 110b may be the green subpixel G, the subpixel 110c may be the blue subpixel B, and the subpixel 110d may be a white subpixel W. Note that in the pixel 110, the positions of the subpixel 110a, the subpixel 110b, the subpixel 110c, and the subpixel 110d are not limited thereto, and arbitrarily-chosen two of four can be interchanged.

FIG. 16 illustrates an example in which one subpixel is provided at a position overlapping with one opening included in the conductive layer 104X or the conductive layer 104Y in a plan view. In the display apparatus illustrated in FIG. 16, the opening has a substantially square shape.

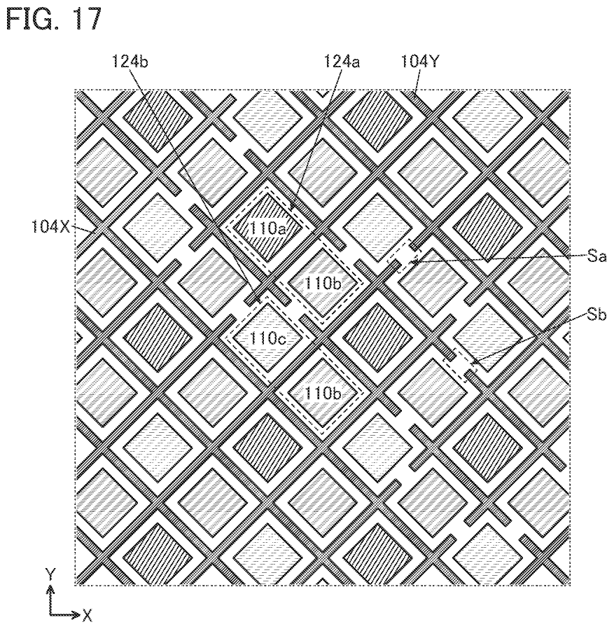

Alternatively, as illustrated in FIG. 17, the pixels 110 may have arrangement such that the arrangement direction of the pixels 110 are tilted at 45°. Specifically, the display apparatus illustrated in FIG. 17 employs PenTile arrangement as in FIG. 10C. In FIG. 17, the pixels 124a including the subpixel 110a and the subpixel 110b and the pixels 124b including the subpixel 110b and the subpixel 110c are provided. In addition, the column where the pixels 124a are arranged and the column where the pixels 124b are arranged are alternately arranged. For example, the subpixel 110a may be the red subpixel R, the subpixel 110b may be the green subpixel G, and the subpixel 110c may be the blue subpixel B. In that case, the green subpixel G may be smaller than the other subpixels as illustrated in FIG. 10C.

The arrangement of the conductive layer 104X and the conductive layer 104Y is arrangement where the arrangement illustrated in FIG. 16 is tilted at 45°. The conductive layer 104X and the conductive layer 104Y have the lattice-shaped top surfaces inclined to, for example, the outline of a display portion of a display apparatus or the extending direction of a wiring connected to the pixel.

The conductive layer 104X and the conductive layer 104Y are separated from each other by notches Sa provided in portions extending from the lower left to the upper right of the lattice-shaped conductive layer and notches Sb provided in portions extending from the upper left to the lower right of the lattice-shaped conductive layer.

Here, when the conductive layer 104X and the conductive layer 104Y are separated, they can be separated linearly by using only one of the notches Sa or the notches Sb. However, it is preferable that the notches Sa and the notches Sb be used in combination and the conductive layer 104X and the conductive layer 104Y be separated so that a boundary therebetween has a zigzag shape as illustrated in FIG. 17, in which case, the patterns of the conductive layer 104X and the conductive layer 104Y can be less likely to be recognized when seen from the display surface side. Furthermore, when the boundary between the conductive layer 104X and the conductive layer 104Y has the zigzag shape, the boundary line can be elongated, an effect of increasing the capacitance between the conductive layer 104X and the conductive layer 104Y can also be obtained.

The touch sensor with such a structure is preferable because the display quality of an image can be further improved.

This embodiment can be combined with the other embodiments as appropriate.

### Embodiment 4

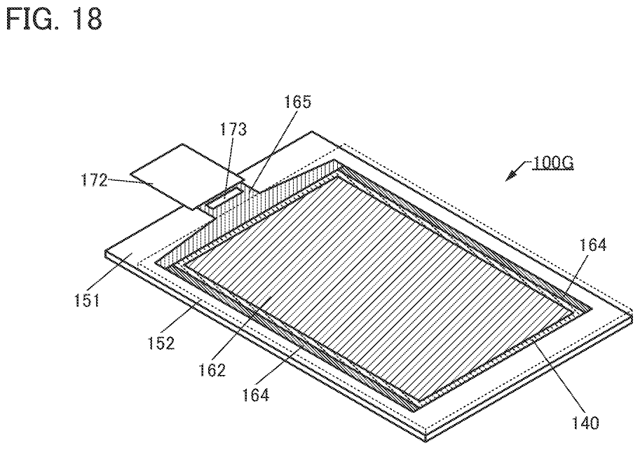

In this embodiment, a display apparatus of one embodiment of the present invention is described with reference to FIG. 18 to FIG. 21.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

The display apparatus of this embodiment can be a high-resolution display apparatus. Accordingly, the display apparatus in this embodiment can be used for display portions of information terminals (wearable devices) such as watch-type and bracelet-type information terminals and display portions of wearable devices capable of being worn on a head, such as a VR device like a head-mounted display and a glasses-type AR device.

### [Display Apparatus 100G]

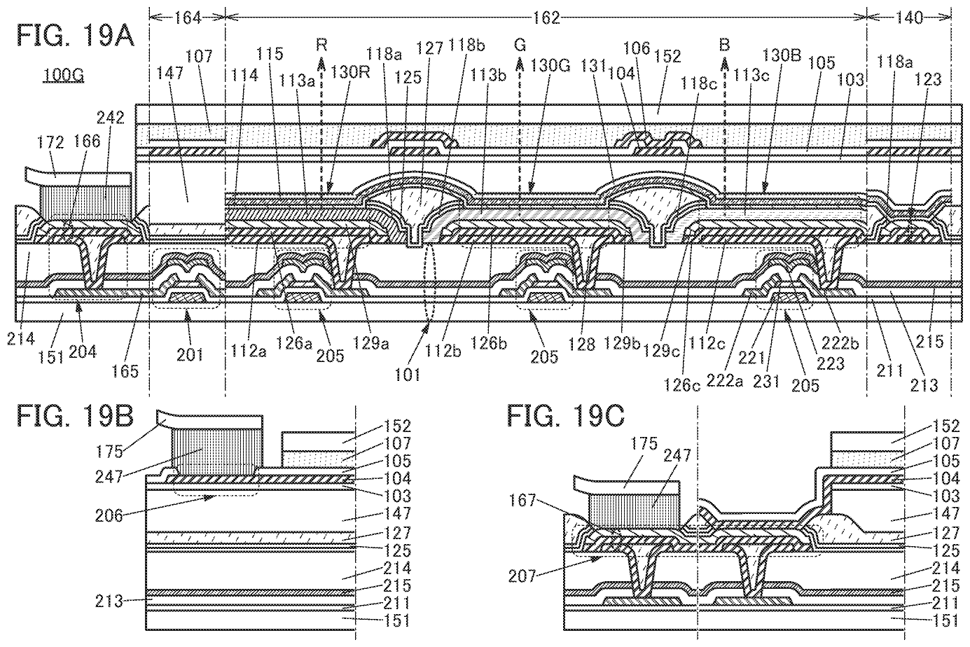

FIG. 18 is a perspective view of a display apparatus 10G, and FIG. 19A is a cross-sectional view of the display apparatus 100G.

In the display apparatus 10G, a substrate 152 and a substrate 151 are bonded to each other. In FIG. 18, the substrate 152 is denoted by the dashed line.

The display apparatus 100G includes a display portion 162, the connection portion 140, a circuit 164, a wiring 165, and the like. FIG. 18 illustrates an example where an IC 173 and an FPC 172 are mounted on the display apparatus 100G. Thus, the structure illustrated in FIG. 18 can be regarded as a display module including the display apparatus 10G, the IC (integrated circuit), and the FPC.

The connection portion 140 is provided outside the display portion 162. The connection portion 140 can be provided along one or more sides of the display portion 162. The number of connection portions 140 can be one or more. FIG. 18 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 18 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 19A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 19A includes a transistor 201, a transistor 205, a light-emitting device 130R emitting red light, a light-emitting device 130G emitting green light, a light-emitting device 130B emitting blue light, the touch sensor, and the like between the substrate 151 and the substrate 152.

The light-emitting devices 130R, 130G, and 130B each have the stacked-layer structure illustrated in FIG. 1B other than a difference in the structure of the pixel electrode. Embodiment 1 can be referred to for the details of the light-emitting devices. For example, the light-emitting device 130R, the light-emitting device 130G, and the light-emitting device 130B corresponds to the light-emitting device 130a, the light-emitting device 130b, and the light-emitting device 130c, each of which is illustrated in FIG. 1B, respectively. The touch sensor also has a structure similar to that in FIG. 1B, and includes the conductive layer 104, the conductive layer 106, the insulating layer 105, and the like.

Since the first layer 113a, the second layer 113b, and the third layer 113c are separated from each other in the display apparatus 100G, crosstalk generated between adjacent subpixels can be inhibited while the display apparatus has high resolution. Accordingly, the display apparatus can have high resolution and high display quality.

The light-emitting device 130R includes a conductive layer 112a, a conductive layer 126a over the conductive layer 112a, and a conductive layer 129a over the conductive layer 126a. All of the conductive layers 112a, 126a, and 129a can be referred to as pixel electrodes, or one or two of them can be referred to as pixel electrodes.

The light-emitting device 130G includes a conductive layer 112b, a conductive layer 126b over the conductive layer 112b, and a conductive layer 129b over the conductive layer 126b.

The light-emitting device 130B includes a conductive layer 112c, a conductive layer 126c over the conductive layer 112c, and a conductive layer 129c over the conductive layer 126c.

The conductive layer 112a is connected to a conductive layer 222b included in the transistor 205 through an opening provided in an insulating layer 214. An end portion of the conductive layer 126a is located outward from the end portion of the conductive layer 112a. The end portion of the conductive layer 126a and an end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

Detailed description of the conductive layers 112b, 126b, and 129b of the light-emitting device 130G and the conductive layers 112c, 126c, and 129c of the light-emitting device 130B is omitted because these conductive layers are similar to the conductive layers 112a, 126a, and 129a of the light-emitting device 130R.

Concave portions are formed in the conductive layers 112a, 112b, and 112c to cover the openings provided in the insulating layer 214. A layer 128 is embedded in the concave portion.

The layer 128 has a planarization function for the concave portions of the conductive layers 112a, 112b, and 112c. The conductive layers 126a, 126b, and 126c electrically connected to the conductive layers 112a, 112b, and 112c, respectively, are provided over the conductive layers 112a, 112b, and 112c and the layer 128. Thus, regions overlapping with the concave portions of the conductive layers 112a, 112b, and 112c can also be used as the light-emitting regions, increasing an aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development processes, reducing the influence of dry etching, wet etching, or the like on the surfaces of the conductive layers 112a, 112b, and 112c. When the layer 128 is formed using a negative photosensitive resin, the layer 128 can sometimes be formed using the same photomask (light-exposure mask) as the photomask used for forming the opening in the insulating layer 214.

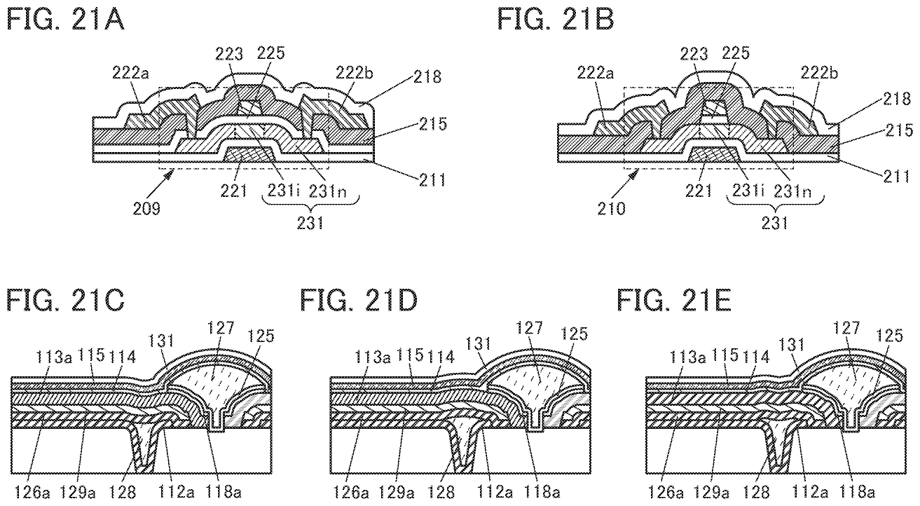

Note that although FIG. 19A illustrates an example where the top surface of the layer 128 includes a planar portion, the shape of the layer 128 is not particularly limited. FIG. 21C to FIG. 21E each illustrate a variation example of the layer 128.

As illustrated in FIG. 21C and FIG. 21E, the top surface of the layer 128 can have a shape such that its center and the vicinity thereof are recessed, i.e., a shape including a concave surface, in a cross-sectional view.

As illustrated in FIG. 21D, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The height of the top surface of the layer 128 and the level of the top surface of the conductive layer 112a may be equal to or substantially equal to each other, or may be different from each other. For example, the level of the top surface of the layer 128 may be either lower or higher than the level of the top surface of the conductive layer 112a.

FIG. 21C can be regarded as illustrating an example where the layer 128 fits in the concave portion of the conductive layer 112a. In contrast, as illustrated in FIG. 21E, the layer 128 may exist also outside the concave portion of the conductive layer 112a, that is, the layer 128 may be formed to have a top surface wider than the concave portion.

The top surface and the side surface of the conductive layer 126a and the top surface and the side surface of the conductive layer 129a are covered with the first layer 113a. Similarly, the top surface and the side surface of the conductive layer 126b and the top surface and the side surface of the conductive layer 129b are covered with the second layer 113b. Moreover, the top surface and the side surface of the conductive layer 126c and the top surface and the side surface of the conductive layer 129c are covered with the third layer 113c. Accordingly, a region provided with the conductive layers 126a, 126b, and 126c can be entirely used as the light-emitting regions of the light-emitting devices 130R, 130G, and 130B, whereby an aperture ratio of the pixels can be increased.

The side surfaces of the first layer 113a, the second layer 113b, and the third layer 113c are covered with the insulating layers 125 and 127. The mask layer 118a is located between the first layer 113a and the insulating layer 125. The mask layer 118b is located between the second layer 113b and the insulating layer 125, and the mask layer 118c is located between the third layer 113c and the insulating layer 125. The common layer 114 is provided over the first layer 113a, the second layer 113b, the third layer 113c, and the insulating layers 125 and 127. The common electrode 115 is provided over the common layer 114. The common layer 114 and the common electrode 115 are each one continuous film shared by the plurality of light-emitting devices.

The protective layer 131 is provided over each of the light-emitting devices 130R, 130G, and 130B. The protective layer 131 covering the light-emitting devices can inhibit an impurity such as water from entering the light-emitting devices, and increase the reliability of the light-emitting devices.

Like the display apparatus 100 illustrated in FIG. 1B, in the display apparatus 100G, the resin layer 147, the insulating layer 103, the conductive layer 104, the insulating layer 105, and the conductive layer 106 are provided over the protective layer 131. Also in the display apparatus 100G, as in the above embodiment, at least part of the conductive layer 104 and part of the conductive layer 106 preferably overlap with the region interposed between two adjacent light-emitting devices or the region interposed between two adjacent EL layers. Furthermore, at least part of the conductive layer 104 and part of the conductive layer 106 preferably include a region overlapping with the insulating layer 127. With such a structure, the touch sensor can be provided while a high aperture ratio of the display apparatus is maintained. Note that the description in Embodiment 1 can be referred to for the components of the touch sensor.

The insulating layer 105, the insulating layer 106, and the substrate 152 are bonded to each other with an adhesive layer 107. A solid sealing structure, a hollow sealing structure, or the like can be employed to seal the light-emitting devices. In FIG. 19A, a solid sealing structure is employed in which a space between the substrate 152 and the substrate 151 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

The conductive layer 123 is provided over the insulating layer 214 in the connection portion 140. An example is described in which the conductive layer 123 has a stacked-layer structure of a conductive film obtained by processing the same conductive film as the conductive layers 112a, 112b, and 112c; a conductive film obtained by processing the same conductive film as the conductive layers 126a, 126b, and 126c; and a conductive film obtained by processing the same conductive film as the conductive layers 129a, 129b, and 129c. The end portion of the conductive layer 123 is covered with the mask layer 118a, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly and electrically connected to each other.

The display apparatus 100G has a top-emission structure. Light emitted by the light-emitting device is emitted toward the substrate 152. For the substrate 152, a material having a high visible-light-transmitting property is preferably used. The pixel electrode contains a material that reflects visible light, and a counter electrode (the common electrode 115) contains a material that transmits visible light.

A stacked-layer structure including the substrate 151 and the components thereover up to the insulating layer 214 corresponds to the substrate 101 and a layer including transistors there above in Embodiment 1.

The transistor 201 and the transistor 205 are formed over the substrate 151. These transistors can be manufactured using the same material in the same process.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a concave portion can be inhibited from being formed in the insulating layer 214 at the time of processing the conductive layer 112a, the conductive layer 126a, the conductive layer 129a, or the like. Alternatively, a concave portion may be formed in the insulating layer 214 at the time of processing the conductive layer 112a, the conductive layer 126a, the conductive layer 129a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is located between the conductive layer 221 and the semiconductor layer 231. The insulating layer 213 is located between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure in which the semiconductor layer where a channel is formed is interposed between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor and a semiconductor having crystallinity (a microcrystalline semiconductor, a polycrystalline semiconductor, a single crystal semiconductor, or a semiconductor partly including crystal regions) may be used. A semiconductor having crystallinity is preferably used, in which case degradation of the transistor characteristics can be inhibited.

The semiconductor layer of the transistor preferably contains a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, and costs of components and mounting cost can be reduced.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display panel can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the EL devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black floating”, “increase in emission luminance”, “increase in gray level”, “inhibition of variation in light-emitting devices”, and the like.

The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin.

It is particularly preferable that an oxide containing indium (In), gallium (Ga), and zinc (Zn) be used for the semiconductor layer. Alternatively, it is preferable to use an oxide containing indium, tin, and zinc. Alternatively, it is preferable to use an oxide containing indium, gallium, tin, and zinc. Alternatively, an oxide containing indium (In), aluminum (Al), and zinc (Zn) (also referred to as IAZO) is preferably used for the semiconductor layer. Alternatively, an oxide containing indium (In), aluminum (Al), gallium (Ga), and zinc (Zn) (also referred to as IAGZO) is preferably used for the semiconductor layer.

When the semiconductor layer is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure where an LTPS transistor and an OS transistor are used in combination is referred to as LTPO in some cases. Note that as a more preferable example, it is preferable to use an OS transistor as a transistor or the like functioning as a switch for controlling electrical continuity between wirings and an LTPS transistor as a transistor or the like for controlling current.

For example, one of the transistors included in the display portion 162 functions as a transistor for controlling a current flowing through the light-emitting device and can also be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the display portion 162 functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display can be achieved.

The structure of the OS transistor is not limited to the structure illustrated in FIG. 19A. For example, the structures illustrated in FIG. 21A and FIG. 21B may be employed.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is located between the conductive layer 221 and the channel formation region 231i. The insulating layer 225 is located at least between the conductive layer 223 and the channel formation region 231i. Furthermore, an insulating layer 218 covering the transistor may be provided.

FIG. 21A illustrates an example of the transistor 209 in which the insulating layer 225 covers the top and side surfaces of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 21B, the insulating layer 225 overlaps with the channel formation region 231i of the semiconductor layer 231 and does not overlap with the low-resistance regions 231n. The structure illustrated in FIG. 21B can be formed by processing the insulating layer 225 with the conductive layer 223 as a mask, for example. In FIG. 21B, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layers 112a, 112b, and 112c, a conductive film obtained by processing the same conductive film as the conductive layers 126a, 126b, and 126c, and a conductive film obtained by processing the same conductive film as the conductive layers 129a, 129b, and 129c. The conductive layer 166 is exposed on the top surface of the connection portion 204. Thus, the connection portion 204 and the FPC 172 can be electrically connected to each other through the connection layer 242.

A light-blocking layer may be preferably provided on the surface of the substrate 152 that faces the substrate 151. The light-blocking layer can be provided between adjacent light-emitting devices, in the connection portion 140, and in the circuit 164, for example. A variety of optical members can be placed on the outer surface of the substrate 152.

The material that can be used for the substrate 101 and the substrate 102 can be used for each of the substrate 151 and the substrate 152.

As the connection layer 242, an anisotropic conductive film (ACF), an anisotropic conductive paste (ACP), or the like can be used.

FIG. 19A illustrates a structure in which signals and power are supplied from the FPC 172 to the display portion 162 and the like through the connection portion 204. Similarly, as illustrated in FIG. 19B, it is preferable that supplying a signal and power or reading of a signal be performed on the touch sensor through an FPC 175 through a connection portion 206. Although not illustrated in FIG. 19B, a structure in which an IC for the touch sensor is mounted on the FPC 175 can be employed.

The connection portion 206 is provided in a region of the substrate 151 not overlapping with the substrate 152. In the connection portion 206, the conductive layer 104 provided over the insulating layer 103 is electrically connected to the FPC 175 through a connection layer 247. Here, the conductive layer 104 functions as a wiring electrically connected to the touch sensor. On the top surface of the connection portion 206, an opening is provided in the insulating layer 105, and the conductive layer 104 is exposed. Thus, the connection portion 206 and the FPC 175 can be electrically connected to each other through the connection layer 247.

The FPC 175 can have a structure similar to that of the FPC 172. The connection layer 247 can have a structure similar to that of the connection layer 242.

Although the conductive layer 104 is placed over the insulating layer 103 and the conductive layer 104 is connected to the connection layer 247 in FIG. 19B, the present invention is not limited thereto. For example, as illustrated in FIG. 19C, a structure may be employed where the conductive layer 104 is dropped over the insulating layer 214 and then the conductive layer 104 and the connection layer 247 are electrically connected to each other.

In a connection portion 207 illustrated in FIG. 19C, the conductive layer 104 is electrically connected to the FPC 175 through a conductive layer 167 and the connection layer 247. Here, an example is illustrated in which the conductive layer 167 has a stacked-layer structure of a conductive film obtained by processing the same conductive film as the conductive layers 112a, 112b, and 112c, a conductive film obtained by processing the same conductive film as the conductive layers 126a, 126b, and 126c, and a conductive film obtained by processing the same conductive film as the conductive layers 129a, 129b, and 129c. On the top surface of the connection portion 207, the conductive layer 167 is exposed. Thus, the connection portion 207 and the FPC 175 can be electrically connected to each other through the connection layer 247.

With the structure illustrated in FIG. 19C, a stacked-layer structure of the FPC 175, the connection layer 247, and the conductive layer 167 in the connection portion 207 can be similar to a stacked-layer structure of the FPC 172, the connection layer 242, and the conductive layer 166 in the connection portion 204. Thus, the connection between the FPC 175 and the conductive layer 167 can be performed in a manner similar to that of the connection between the FPC 172 and the conductive layer 166; thus, the connection between the FPC 175 and the conductive layer 167 can be performed relatively easily.

Although FIG. 19C illustrates a structure in which the FPC 172 and the FPC 175 are separately provided, the present invention is not limited thereto. A structure in which the connection portion 204 and the connection portion 207 are placed in proximity to each other may be employed such that the connection layer 242 and the connection layer 247, and the FPC 172 and the FPC 175 are integrated. With such a structure, the FPC for display and the FPC for the touch sensor can be collectively provided; thus, these mounting areas can be reduced, whereby a display apparatus or an electronic device using the display apparatus can be made smaller and can have a narrower frame.

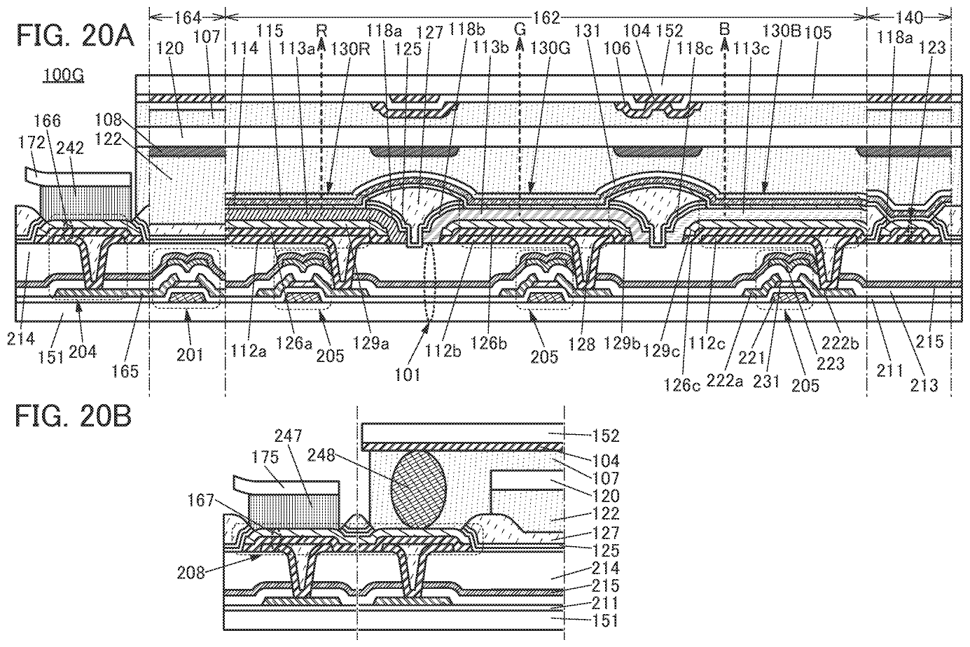

In FIG. 19A, although the structure of the touch sensor is similar to the structure illustrated in FIG. 1B, the present invention is not limited thereto, and the touch sensor described in the above embodiment can be used as appropriate. For example, as illustrated in FIG. 20A, the structure of the touch sensor may be similar to that illustrated in FIG. 3C. In the display apparatus 100G illustrated in FIG. 20A, a layer including the light-emitting devices and the transistors is provided between the substrate 151 and the substrate 120, and the touch sensor is provided over the substrate 152. The light-blocking layer 108 may be provided on the surface of the substrate 120 that faces the substrate 151. Here, the substrate 120 and the substrate 151 are bonded to each other with the adhesive layer 122. In this case, the adhesive layer 122 is in contact with the substrate 120, the light-blocking layer 108, and the protective layer 131. The substrate 120 and the substrate 152 are bonded to each other with the adhesive layer 107. In this case, the adhesive layer 107 is in contact with the substrate 120, the insulating layer 105, and the conductive layer 106.

In the display apparatus illustrated in FIG. 20A, although the substrate 152 and the substrate 151 overlap with each other as illustrated in FIG. 20B, a connection portion 208, the conductive layer 104, and a conductive particle 248 are provided in a region where the substrate 152 and the substrate 151 overlap with each other and the substrate 120 overlaps with neither the substrate 152 nor the substrate 151. In the connection portion 208 illustrated in FIG. 20B, the conductive layer 104 is electrically connected to the conductive layer 167 through the conductive particle 248. When the conductive particle 248 is provided in this manner, the conductive layer 104 and the conductive layer 167 that are provided on different substrates can be electrically connected to each other. Moreover, on the top surface of the connection portion 208, the conductive layer 167 is exposed. Thus, the connection portion 208 and the FPC 175 can be electrically connected to each other through the connection layer 247.

As the conductive particle 248, a particle of a resin, silica, or the like coated with a metal material is used. It is preferable to use nickel or gold as the metal material because contact resistance can be reduced. It is also preferable to use a particle coated with layers of two or more kinds of metal materials, such as a particle coated with nickel and further with gold.

This embodiment can be combined with the other embodiments as appropriate.

### Embodiment 5

In this embodiment, a structure example of a transistor that can be used in the display apparatus of one embodiment of the present invention will be described. Specifically, the case of using a transistor containing silicon in a semiconductor where a channel is formed will be described.

One embodiment of the present invention is a display apparatus including light-emitting devices and a pixel circuit. For example, three kinds of light-emitting devices emitting light of red (R), green (G), and blue (B) are included, whereby a full-color display apparatus can be achieved.

Transistors containing silicon in their semiconductor layers where channels are formed are preferably used as all transistors included in the pixel circuit for driving the light-emitting device. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, such as LTPS transistors, a circuit required to be driven at a high frequency (e.g., a source driver circuit) can be formed on the same substrate as the display portion. Thus, external circuits mounted on the display apparatus can be simplified, whereby costs of components and mounting costs can be reduced.

It is preferable to use a transistor containing a metal oxide (hereinafter also referred to as an oxide semiconductor) in its semiconductor layer where a channel is formed (hereinafter such a transistor is also referred to as an OS transistor) as at least one of the transistors included in the pixel circuit. An OS transistor has extremely higher field-effect mobility than a transistor containing amorphous silicon. In addition, an OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

When an LTPS transistor is used as one or more of the transistors included in the pixel circuit and an OS transistor is used as the rest, the display apparatus can have low power consumption and high driving capability. In a more favorable example, it is preferable that an OS transistor be used as a transistor functioning as a switch for controlling electrical continuity between wirings and an LTPS transistor be used as a transistor for controlling current.

For example, one of the transistors included in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In this case, the amount of current flowing through the light-emitting device can be increased in the pixel circuit.

Another transistor included in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

More specific structure examples will be described below with reference to drawings.

### [Structure Example 2 of Display Apparatus]

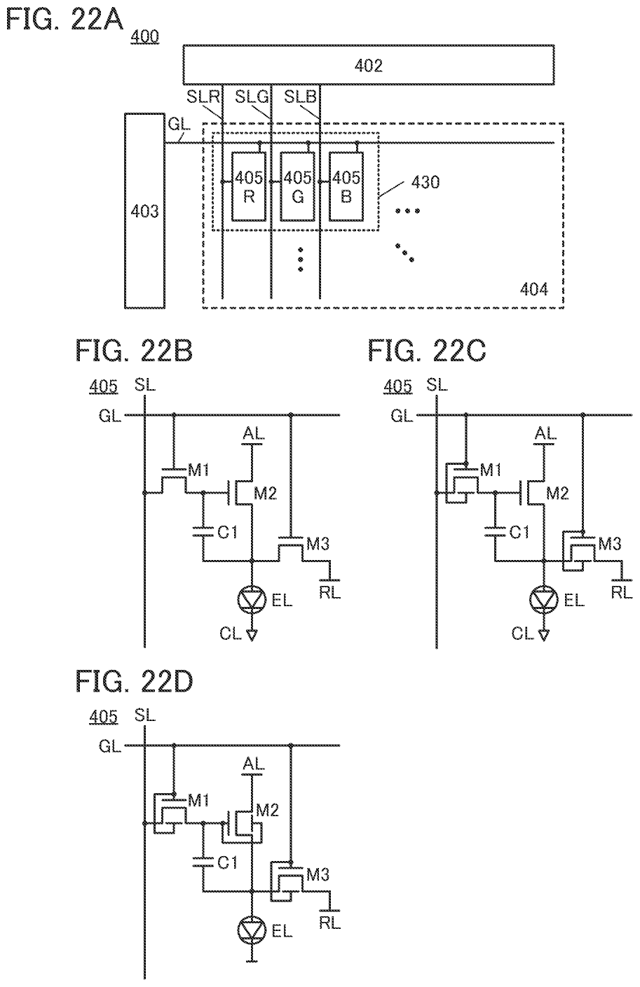

FIG. 22A illustrates a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting device functioning as a display device.

The pixel 430 is electrically connected to a wiring GL, a wiring SLR, a wiring SLG, and a wiring SLB. The wiring SLR, the wiring SLG, and the wiring SLB are electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting device that emits red light. The subpixel 405G includes a light-emitting device that emits green light. The subpixel 405B includes a light-emitting device that emits blue light. Thus, the display apparatus 400 can perform full-color display. Note that the pixel 430 may include a subpixel including a light-emitting device emitting light of another color. For example, the pixel 430 may include, in addition to the three subpixels, a subpixel including a light-emitting device emitting white light, a subpixel including a light-emitting device emitting yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 22B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting device EL. The wiring GL and a wiring SL are electrically connected to the pixel 405. The wiring SL corresponds to any of the wiring SLR, the wiring SLG, and the wiring SLB illustrated in FIG. 22A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be set such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. For example, the transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In that case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor including an oxide semiconductor in its semiconductor layer where a channel is formed can be used. The semiconductor layer preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. In particular, an oxide containing indium, gallium, and zinc is preferably used for a semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and smaller carrier density than silicon can achieve an extremely low off-state current. Thus, such a low off-state current enables long-term retention of charge accumulated in a capacitor that is connected to the transistor in series. Therefore, it is particularly preferable to use a transistor including an oxide semiconductor as the transistor M1 and the transistor M3 each of which is connected to the capacitor C1 in series. The use of the transistor including an oxide semiconductor as each of the transistor M1 and the transistor M3 can inhibit leakage of charge retained in the capacitor C1 through the transistor M1 or the transistor M3. Furthermore, since charge retained in the capacitor C1 can be retained for a long time, a still image can be displayed for a long time without rewriting data in the pixel 405.

Note that although the transistor is illustrated as an n-channel transistor in FIG. 22B, a p-channel transistor can also be used.

The transistors included in the pixel 405 are preferably formed to be arranged over the same substrate.

Transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 22C is an example where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 22D is an example where a transistor including a pair of gates (hereinafter referred to as a first gate and a second gate in some cases) is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

FIG. 22D illustrates a case where the first gate and the second gate of the transistor M2 are electrically connected to each other, but the present invention is not limited thereto. The first gate of the transistor M2 may be electrically connected to the other of the source and the drain of the transistor M1 and one electrode of the capacitor C1, and the second gate of the transistor M2 may be electrically connected to the other of the source and the drain of the transistor M2, one of the source and the drain of the transistor M3, the other electrode of the capacitor C1, and one electrode of the light-emitting device EL.

### [Structure Example of Transistor]

Cross-sectional structure examples of a transistor that can be used in the display apparatus described above are described below.

### [Structure Example 1]

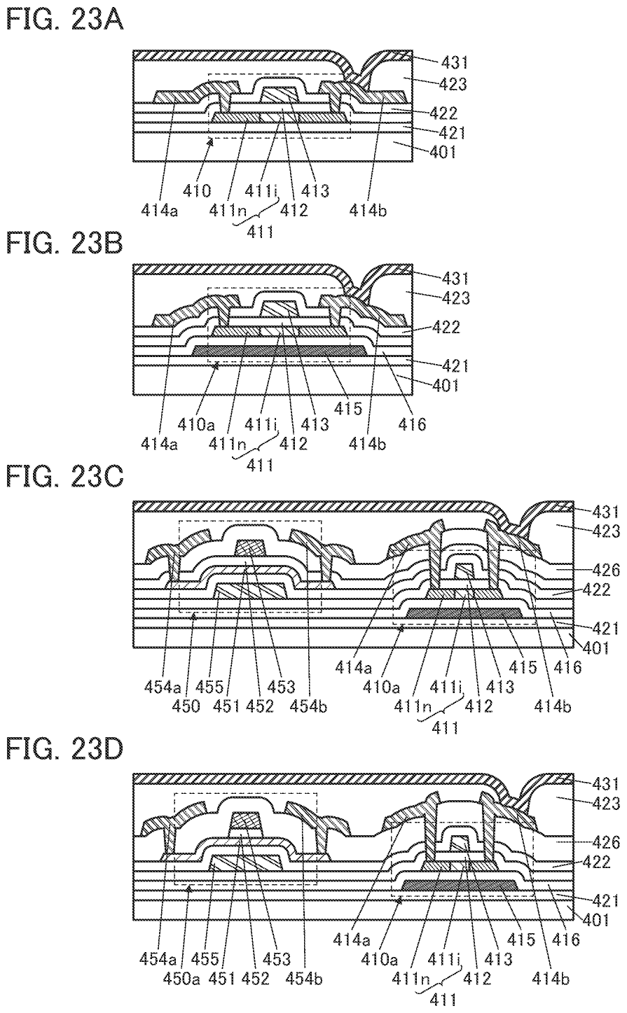

FIG. 23A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 23A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can include a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance region 411n in the opening portion provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### [Structure Example 2]

FIG. 23B illustrates a transistor 410a including a pair of gate electrodes. The transistor 410a illustrated in FIG. 23B is different from FIG. 23A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 23B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 illustrated in FIG. 23A as an example or the transistor 410a illustrated in FIG. 23B as an example can be used. In this case, the transistors 410a may be used as all of the transistors included in the pixels 405, the transistors 410 may be used as all of the transistors, or the transistors 410a and the transistors 410 may be used in combination.

### [Structure Example 3]

Described below is an example of a structure including both a transistor containing silicon in its semiconductor layer and a transistor containing a metal oxide in its semiconductor layer.

FIG. 23C is a schematic cross-sectional view including the transistor 410a and a transistor 450.

Structure Example 1 described above can be referred to for the structure of the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor including metal oxide in its semiconductor layer. The structure in FIG. 23C illustrates an example in which the transistor 450 corresponds to the transistor M1 in the pixel 405 and the transistor 410a corresponds to the transistor M2. That is, FIG. 23C illustrates an example in which one of a source and a drain of the transistor 410a is electrically connected to the conductive layer 431.

Moreover, FIG. 23C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in opening portions provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b. In FIG. 23C, the conductive layer 414a, the conductive layer 414b, the conductive layer 454a, and the conductive layer 454b are formed on the same plane (i.e., in contact with the top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 23C illustrates a structure where the conductive layer 413 and the conductive layer 455 are formed on the same plane (i.e., in contact with the top surface of the insulating layer 412) and contain the same metal element. This is preferable because the manufacturing process can be simplified.

In the structure in FIG. 23C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in the transistor 450a illustrated in FIG. 23D.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is located inward from the lower layer or the upper layer is located outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with the other embodiments as appropriate.

### Embodiment 6

In this embodiment, a light-emitting device that can be used for the display apparatus according to one embodiment of the present invention will be described.

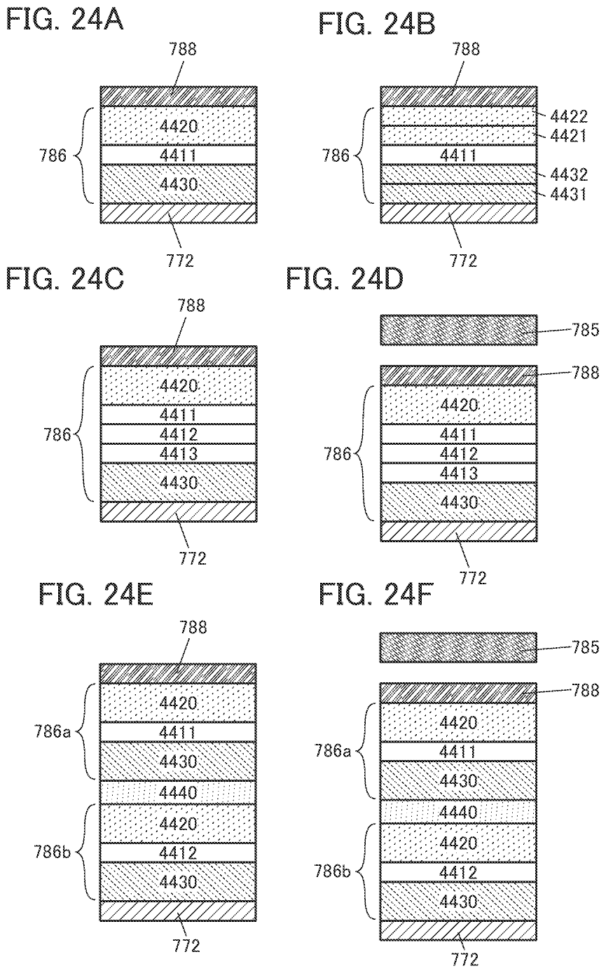

As illustrated in FIG. 24A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between a pair of electrodes, can function as a single light-emitting unit, and the structure in FIG. 24A is referred to as a single structure in this specification.

FIG. 24B is a variation example of the EL layer 786 included in the light-emitting device illustrated in FIG. 24A. Specifically, the light-emitting device illustrated in FIG. 24B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. When the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layer structure, carriers can be efficiently injected to the light-emitting layer 4411, and the efficiency of the recombination of carriers in the light-emitting layer 4411 can be enhanced.

Note that the structure where a plurality of light-emitting layers (light-emitting layers 4411, 4412, and 4413) are provided between the layer 4420 and the layer 4430 as illustrated in FIG. 24C and FIG. 24D is also a variation of the single structure.

A structure in which a plurality of light-emitting units (an EL layer 786a and an EL layer 786b) are connected in series with a charge-generation layer 4440 therebetween as illustrated in FIG. 24E or FIG. 24F is referred to as a tandem structure in this specification. Note that a tandem structure may be referred to as a stack structure. The tandem structure enables a light-emitting device capable of high-luminance light emission.

In FIG. 24C and FIG. 24D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 24D.

Alternatively, light-emitting materials that emit light of different colors may be used for the light-emitting layer 4411, the light-emitting layer 4412, and the light-emitting layer 4413. White light emission can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 24D. When white light passes through a color filter, light of a desired color can be obtained.

In FIG. 24E and FIG. 24F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when the light-emitting layer 4411 and the light-emitting layer 4412 emit light of complementary colors. FIG. 24F illustrates an example where the layer 785 is further provided. One or both of a color conversion layer and a color filter (coloring layer) can be used as the layer 785.

Note that also in FIG. 24C, FIG. 24D, FIG. 24E, and FIG. 24F, the layer 4420 and the layer 4430 may each have a stacked-layer structure of two or more layers as illustrated in FIG. 24B.

A structure in which light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, white, or the like depending on the material that constitutes the EL layer 786. Furthermore, the color purity can be further increased when the light-emitting device has a microcavity structure.

The light-emitting device that emits white light preferably contains two or more kinds of light-emitting substances in the light-emitting layer. To obtain white light emission, two or more kinds of light-emitting substances are selected such that their emission colors are complementary. For example, when an emission color of a first light-emitting layer and an emission color of a second light-emitting layer are complementary colors, the light-emitting device can be configured to emit white light as a whole. The same applies to a light-emitting device including three or more light-emitting layers.

The light-emitting layer preferably contains two or more light-emitting substances that emit light of R (red), G (green), B (blue), Y (yellow), O (orange), and the like. Alternatively, a light-emitting layer preferably contains two or more light-emitting substances each of which emits light containing two or more of spectral components of R, G, and B.

This embodiment can be combined with the other embodiments as appropriate.

### Embodiment 7

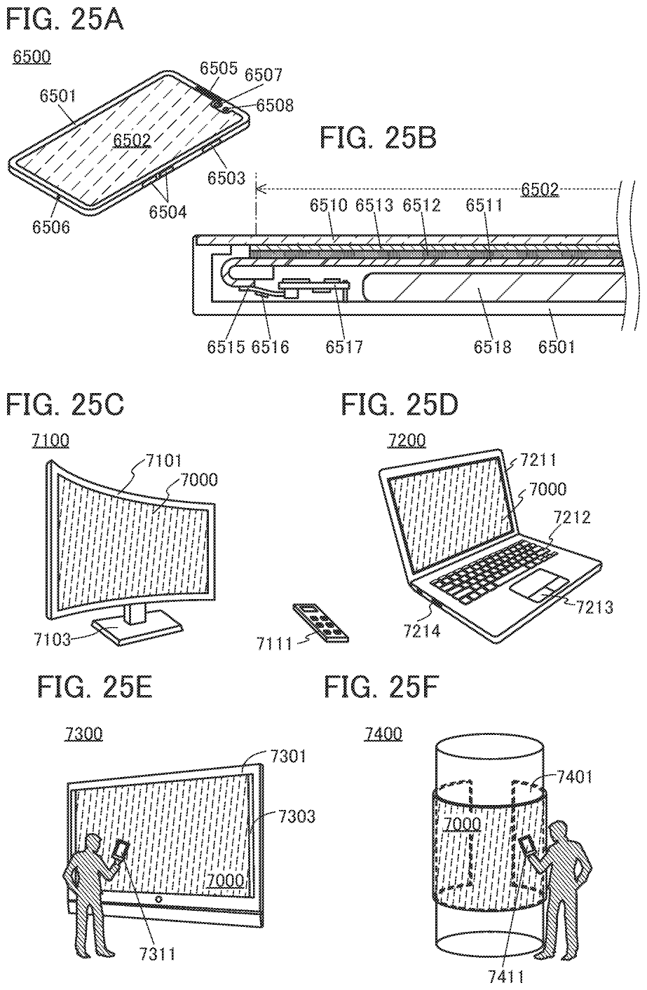

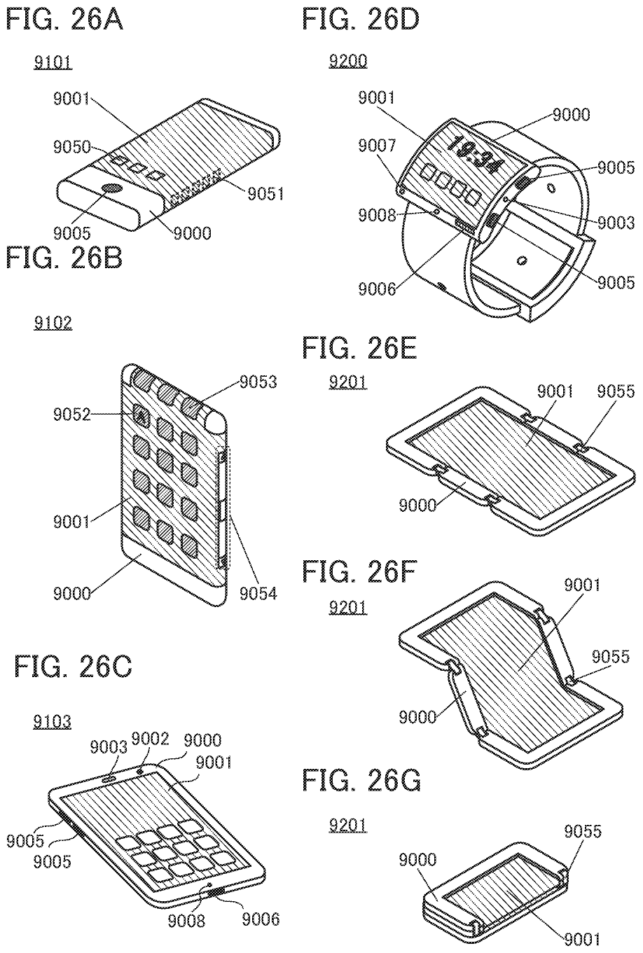

In this embodiment, electronic devices of one embodiment of the present invention are described with reference to FIG. 25 and FIG. 26.

Electronic devices of this embodiment each include the display apparatus of one embodiment of the present invention in a display portion. The display apparatus of one embodiment of the present invention can be easily increased in resolution and definition and can achieve high display quality. Thus, the display apparatus of one embodiment of the present invention can be used for a display portion of a variety of electronic devices. As described in the above embodiment, the display apparatus of one embodiment of the present invention can have a high aperture ratio and the touch sensor.

Examples of the electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, a display apparatus of one embodiment of the present invention can have high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR (Mixed Reality) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions, for example, a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 25A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 25B is a schematic cross-sectional view including an end portion of the housing 6501 on the microphone 6506 side.

A protective member 6510 having a light-transmitting property is provided on a display surface side of the housing 6501, and a display apparatus 6511, an optical member 6512, a touch sensor panel 6513, a printed circuit board 6517, a battery 6518, and the like are placed in a space surrounded by the housing 6501 and the protective member 6510.

The display apparatus 6511, the optical member 6512, and the touch sensor panel 6513 are fixed to the protective member 6510 with an adhesive layer (not illustrated).

Part of the display apparatus 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be achieved. Since the display apparatus 6511 is extremely thin, the battery 6518 with high capacity can be mounted without an increase in the thickness of the electronic device. Moreover, part of the display apparatus 6511 is folded back so that a connection portion with the FPC 6515 is placed on the back side of a pixel portion, whereby an electronic device with a narrow frame can be achieved.

FIG. 25C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 25C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 25D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 25E and FIG. 25F illustrate examples of digital signage.

Digital signage 7300 illustrated in FIG. 25E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 25F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 25E and FIG. 25F.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 25E and FIG. 25F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

Electronic devices illustrated in FIG. 26A to FIG. 26G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 26A to FIG. 26G.

The electronic devices illustrated in FIG. 26A to FIG. 26G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 26A to FIG. 26G are described below.

FIG. 26A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 26A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 26B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 26C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 26D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 26E to FIG. 26G are perspective views illustrating a foldable portable information terminal 9201. FIG. 26E is a perspective view of an opened state of the portable information terminal 9201, FIG. 26G is a perspective view of a folded state thereof, and FIG. 26F is a perspective view of a state in the middle of change from one of FIG. 26E and FIG. 26G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined with the other embodiments as appropriate.

### REFERENCE NUMERALS

AL: wiring, CL: wiring, Cp: capacitance, GL: wiring, RL: wiring, Sa: notch, Sb: notch, SL: wiring, SLB: wiring, SLG: wiring, SLR: wiring, Sx: notch, Sy: notch, 100G: display apparatus, 100: display apparatus, 101: substrate, 102: substrate, 103: insulating layer, 104t: conductive layer, 104X: conductive layer, 104Y: conductive layer, 104: conductive layer, 105: insulating layer, 106t: conductive layer, 106: conductive layer, 107: adhesive layer, 108: light-blocking layer, 110a: subpixel, 110b: subpixel, 110c: subpixel, 110d: subpixel, 110: pixel, 111a: pixel electrode, 111b: pixel electrode, 111c: pixel electrode, 111: pixel electrode, 112a: conductive layer, 112b: conductive layer, 112c: conductive layer, 113a: first layer, 113b: second layer, 113c: third layer, 114: common layer, 115: common electrode, 118a: mask layer, 118b: mask layer, 118c: mask layer, 118: mask layer, 120: substrate, 121: insulating layer, 122: adhesive layer, 123: conductive layer, 124a: pixel, 124b: pixel, 125: insulating layer, 126a: conductive layer, 126b: conductive layer, 126c: conductive layer, 127: insulating layer, 128: layer, 129a: conductive layer, 129b: conductive layer, 129c: conductive layer, 130a: light-emitting device, 130B: light-emitting device, 130b: light-emitting device, 130c: light-emitting device, 130G: light-emitting device, 130R: light-emitting device, 130: light-emitting device, 131: protective layer, 135: gap, 139: region, 140: connection portion, 145: adhesive layer, 146: substrate, 147: resin layer, 148: resin layer, 151: substrate, 152: substrate, 162: display portion, 164: circuit, 165: wiring, 166: conductive layer, 167: conductive layer, 172: FPC, 173: IC, 175: FPC, 201: transistor, 204: connection portion, 205: transistor, 206: connection portion, 207: connection portion, 208: connection portion, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 242: connection layer, 247: connection layer, 248: conductive particle, 255a: insulating layer, 255b: insulating layer, 255c: insulating layer, 400: display apparatus, 401: substrate, 402: driver circuit portion, 403: driver circuit portion, 404: display portion, 405B: subpixel, 405G: subpixel, 405R: subpixel, 405: pixel, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 431: conductive layer, 450a: transistor, 450: transistor, 451: semiconductor layer, 452: insulating layer, 453: conductive layer, 454a: conductive layer, 454b: conductive layer, 455: conductive layer, 772: lower electrode, 785: layer, 786a: EL layer, 786b: EL layer, 786: EL layer, 788: upper electrode, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protective member, 6511: display apparatus, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first pixel;
a second pixel placed adjacent to the first pixel,
a first conductive layer, a second conductive layer, and
a first insulating layer,
wherein the first pixel comprises a first pixel electrode, a first EL layer over the first pixel electrode, and a common electrode over the first EL layer,
wherein the second pixel comprises a second pixel electrode, a second EL layer over the second pixel electrode, and the common electrode over the second EL layer,
wherein the first conductive layer is placed over the common electrode,
wherein the first insulating layer is placed over the first conductive layer,
wherein the second conductive layer is placed over the first insulating layer,
wherein one or both of the first conductive layer and the second conductive layer overlap with a region interposed between the first EL layer and the second EL layer, and
wherein a side surface of the first EL layer and a side surface of the second EL layer are placed to face each other.

2. The display apparatus according to claim 1, further comprising:
a second insulating layer; and
third insulating layer over the second insulating layer,
wherein the second insulating layer contains an inorganic material,
wherein the third insulating layer contains an organic material,
wherein a part of the second insulating layer and a part of the third insulating layer are placed at a position interposed between an end portion of the side surface of the first EL layer and an end portion of the side surface of the second EL layer, and
wherein another part of the third insulating layer overlaps with a part of a top surface of the first EL layer and a part of a top surface of the second EL layer with the second insulating layer therebetween.

3. The display apparatus according to claim 2, wherein one or both of the first conductive layer and the second conductive layer comprise a region overlapping with the third insulating layer.

4. The display apparatus according to claim 2, wherein each of a side surface of the first conductive layer and a side surface of the second conductive layer is located inward from an end portion of the third insulating layer in a cross-sectional view.

5. The display apparatus according to claim 2, wherein the common electrode is placed over the third insulating layer.

6. The display apparatus according to claim 1, further comprising a first substrate and a second substrate,
wherein the first pixel and the second pixel are placed over the first substrate, and
wherein the second substrate is bonded to a surface of the first substrate where the first insulating layer and the second conductive layer are placed with an adhesive layer.

7. The display apparatus according to claim 1,
wherein the first pixel comprises a common layer placed between the first EL layer and the common electrode, and
wherein the second pixel comprises the common layer placed between the second EL layer and the common electrode.

8. The display apparatus according to claim 1, wherein the display apparatus comprises a region in which a distance between the first pixel electrode and the second pixel electrode is less than or equal to 8 μm.
